(19) United States
(12) Patent Application Publication
(10) Pub. No.: US 2017/0271604 A1
(43) Pub. Date: Sep. 21, 2017

(54) ENERGY LEVEL MODIFICATION OF NANOCRYSTALS THROUGH LIGAND EXCHANGE

(71) Applicant: Massachusetts Institute of Technology, Cambridge, MA (US)

(72) Inventors: Patrick R. Brown, Cambridge, MA (US); Donghun KIM, Cambridge, MA (US); Moungi G. Bawendi, Cambridge, MA (US); Jeffrey C. Grossman, Brookline, MA (US); Vladimir Bulovic, Lexington, MA (US)

(73) Assignee: Massachusetts Institute of Technology, Cambridge, MA (US)

(21) Appl. No.: 15/309,797

(22) PCT Filed: May 8, 2015
(86) PCT No.: PCT/US15/29886

§ 371 Date: Nov. 8, 2016

Related U.S. Application Data
(60) Provisional application No. 61/990,789, filed on May 9, 2014.

(51) Int. Cl. H01L 51/42; H01L 51/00; H01L 51/44

(52) U.S. Cl. CPC H01L 51/426; H01L 51/441; H01L 51/0077; H01L 2251/301

(57) ABSTRACT

A method of improving performance of a photovoltaic device can include modifying a surface energy level of a nanocrystal through ligand exchange. A photovoltaic device can include a layer that includes a nanocrystal with a surface energy modified through ligand exchange.

### PRIORITY CLAIM

This application claims priority to U.S. Provisional Application No. 61/990,789, filed May 9, 2014, which is incorporated by reference in its entirety.

### FIELD OF THE INVENTION

The invention relates to semiconductor nanocrystals.

### BACKGROUND

Semiconductor nanocrystals (quantum dots) whose radii are smaller than the bulk exciton Bohr radius constitute a class of materials intermediate between molecular and bulk forms of matter. Quantum confinement of both the electron and hole in all three dimensions leads to an increase in the effective band gap of the material with decreasing crystallite size. Semiconductor nanocrystals have been a subject of great interest, promising extensive applications including display devices, information storage, biological tagging materials, photovoltaics, sensors and catalysts.

### SUMMARY

In one aspect, a method of improving performance of a photovoltaic device can include modifying a surface energy level of a semiconductor nanocrystal of the device through ligand exchange. In certain embodiments, the ligand can include a thiol. In certain embodiments, the ligand can include an amine. In certain embodiments, the ligand can include a halide.

In certain embodiments, the semiconductor nanocrystal can include a lead sulfide.

In certain embodiments, the ligand can include a benzenethiol (BT), a 1,2-benzenedithiol, a 1,3-berizenedithiol, a 1,4-benzenedithiol, a 1,2-ethanedithiol, or a 3-mercaptopropionic acid. In certain embodiments, the ligand can include a 1,2-ethylenediatnine or an ammonium thiocyanate. In certain embodiments, the ligand can include a tetrabutylammonium iodide, a tetrabutylammonium bromide, a tetrabutylammonium chloride, or a tetrabutylammonium fluoride.

In another aspect, a photovoltaic device having improved performance can include a first electrode; a first charge transporting layer in contact with the first electrode; a second electrode; a second charge transporting layer in contact with the second electrode; and a plurality of semiconductor nanocrystals disposed between the first charge transporting layer and the second charge transporting layer, wherein a surface of the plurality of semiconductor nanocrystals is modified through ligand exchange. The improved performance can be measured by comparison to a photovoltaic device that has not had the ligand exchange surface modification.

In certain embodiments, the semiconductor nanocrystal includes a lead sulfide.

In certain embodiments; the ligand can include a thiol. In certain embodiments, the ligand can include an amine. In certain embodiments, the ligand can include a halide. In certain embodiments, the ligand can include a benzenethiol (BT), a 1,2-benzenedithiol, a 1,3-benzenedithiol, a 1,4-benzenedithiol, a 1,2-ethanedithiol, or a 3-mercaptopropionic acid. In certain embodiments, the ligand can include a 1,2-ethylenediamine or an ammonium thiocyanate. In certain embodiments, the ligand can include a tetrabutylammonium iodide, a tetrabutylammonium bromide, a tetrabutylammonium chloride, or a tetrabutylammonium fluoride.

In another aspect, a semiconductor nanocrystal can include a surface modified through ligand exchange, wherein the modification improves performance of a photovoltaic device comprising the semiconductor nanocrystal.

In certain embodiments, the ligand can include a thiol. In certain embodiments, the ligand can include an amine. In certain embodiments, the ligand can include a halide. In certain embodiments, the ligand can include a benzenethiol (BT), a 1,2-benzenedithiol, a 1,3-benzenedithiol, a 1,4-benzenedithiol, a 1,2-ethanedithiol, or a 3-mercaptopropionic acid. In certain embodiments, the ligand can include a 1,2-ethylenediamine or an ammonium thiocyanate. In certain embodiments, the ligand can include a tetrabutylammonium iodide, a tetrabutylammonium bromide, a tetrabutylammonium chloride, or a tetrabutylammonium fluoride.

Other aspects, embodiments, and features will be apparent from the following description, the drawings, and the claims.

### BRIEF DESCRIPTION OF THE DRAWINGS

FIG. 1A shows complete ultraviolet photoelectron spectrum of 100 nm thick 1,3-BUT-exchanged PbS QD film on gold; FIG. 1B shows optical absorption spectrum (absorption=1 transmission reflection) of the first excitonic peak of 1,3-BDT-exchanged PbS QDs; FIG. 1C shows energy level diagram of 1,3-BUT-exchanged PbS QDs determined from the spectra in FIGS. 1A and 1B and equation (1); FIG. 1D shows chemical structures of ligands; FIG. 1E shows complete energy level diagrams of PbS QDs exchanged with the ligands shown in FIG. 1D.

FIG. 2A shows a schematic diagram of modeled PbS slab; FIG. 2B shows a plane-averaged electrostatic potentials of PbS slabs with different ligands; FIG. 2C shows density of states of the ligand (filled curve) and ligand-slab system (unfilled curve) for each of the five ligands; FIG. 2D shows vacuum energy shifts (ΔE_{vac}, black arrows) for each ligand and decomposition into interface (ΔE_{vac,1}, red arrows) and intrinsic ligand (ΔE_{vac,2}, blue arrows) dipoles.

FIG. 3A shows photovoltaic performance of ZnO/PbS np-heterojunction; FIG. 3B shows photovoltaic performance of Schottky junction architectures.

FIG. 4A shows the influence of a PEDOT:PSS hole transport layer; FIG. 4B shows the influence of a LiF cathode interlayer.

FIG. 5A shows a device structure of the donor-acceptor heterojunction; FIG. 5B shows a schematic band diagram of the donor-acceptor pair; FIG. 5C shows measured energy levels of three different sizes of PbS QDs; FIG. 5D shows currents of 1,2-BDT-treated QDs of different size paired with C₆₀; FIG. 5E shows currents of 1,3-BDT-treated QDs of different sizes paired with C₆₀; FIG. 5F shows currents of 1,2-BDT and 1,3-BDT-treated QDs of a given size paired with C₆₀; FIG. 5G shows currents of 1,2-BDT-treated QDs paired with PTCBI and C₆₀.

FIG. 6A shows that electronic properties of quantum dots depend on surface chemistry; FIG. 6B shows a schematic drawing depicting a photovoltaic device.

FIG. 7A shows ultraviolet photoelectron spectra of 100 nm thick benzenethiol ligand-exchanged PbS QD films on gold substrates; FIG. 7B shows ultraviolet photoelectron spectra of 100 nm thick 1,2-benzenedithiol ligand-exchanged PbS QD films on gold substrates; FIG. 7C shows ultraviolet photoelectron spectra of 100 nm thick 1,3-benzenedithiol ligand-exchanged PbS QD films on gold substrates; FIG. 7D shows ultraviolet photoelectron spectra of 100 nm thick 1,4-benzenedithiol ligand-exchanged PbS QD films on gold substrates; FIG. 7E shows ultraviolet photoelectron spectra of 100 nm thick 1,2-ethanedithiol ligand-exchanged PbS QD films on gold substrates; FIG. 7F shows ultraviolet photoelectron spectra of 100 nm thick 3-mercaptopropionic acid ligand-exchanged PbS QD films on gold substrates; FIG. 7E shows ultraviolet photoelectron spectra of 100 nm thick ethylenediamine ligand-exchanged PbS QD films on gold substrates; FIG. 7H shows ultraviolet photoelectron spectra of 100 nm thick ammonium thiocyanate ligand-exchanged PbS QD films on gold substrates; FIG. 7I shows ultraviolet photoelectron spectra of 100 nm thick tetrabutylammonium fluoride ligand-exchanged PbS QD films on gold substrates; FIG. 7J shows ultraviolet photoelectron spectra of 100 nm thick tetrabutylammonium chloride ligand-exchanged PbS QD films on gold substrates; FIG. 7K shows ultraviolet photoelectron spectra of 100 nm thick tetrabutylammonium bromide ligand-exchanged PbS QD films on gold substrates; FIG. 7L shows ultraviolet photoelectron spectra of 100 nm thick tetrabutylammonium iodide ligand-exchanged PbS QD films on gold substrates.

FIG. 8 shows time-dependence of energy levels determined from UPS spectra of 1,3-BDT-treated PbS QDs (λ=963 nm first absorption peak in solution).

FIG. 9 shows dependence of UPS results on QD purification procedure for 1,3-BDT-exchanged PbS QDs (λ=963 nm first absorption peak in solution).

FIG. 10 shows optical transmission, reflection, and absorption of 1,3-BDT-exchanged PbS QDs (λ=963 nm first absorption peak in solution).

FIG. 11A shows optical absorption spectra of PbS QDs ligand-exchanged with benzenethiol; FIG. 11B shows optical absorption spectra of PbS QDs ligand-exchanged with 1,2-benzenedithiol; FIG. 11C shows optical absorption spectra of PbS QDs ligand-exchanged with 1,3-benzenedithiol; FIG. 11D shows optical absorption spectra of PbS QDs ligand-exchanged with 1,4-benzenedithiol; FIG. 11E shows optical absorption spectra of PbS QDs ligand-exchanged with 1,2-ethanedithiol; FIG. 11F shows optical absorption spectra of PbS QDs ligand-exchanged with 3-mercaptopropionic acid; FIG. 11G shows optical absorption spectra of PbS QDs ligand-exchanged with ethylenediamine; FIG. 11H shows optical absorption spectra of PbS QDs ligand-exchanged with ammonium thiocyanate; FIG. 11I shows optical absorption spectra of PbS QDs ligand-exchanged with tetrabutylammonium fluoride; FIG. 11J shows optical absorption spectra of PbS QDs ligand-exchanged with tetrabutylammonium chloride; FIG. 11K shows optical absorption spectra of PbS QDs ligand-exchanged with tetrabutylammonium bromide; FIG. 11L shows optical absorption spectra of PbS QDs ligand-exchanged with tetrabutylammonium iodide.

FIG. 12A shows UPS spectra of PbS QDs ligand-exchanged with 1,3-BDT with λ=1153 nm first absorption peak in solution; FIG. 12B shows UPS spectra of PbS QDs ligand-exchanged with 1,2-BDT with λ=1153 nm first absorption peak in solution; FIG. 12C shows UPS spectra of PbS QDs ligand-exchanged with 1,3-BDT with λ=905 nm first absorption peak in solution; FIG. 12D shows UPS spectra of PbS QDs ligand-exchanged with 1,2-DDT with λ=905 nm first absorption peak in solution; FIG. 12E shows UPS spectra of PbS QDs ligand-exchanged with 1,3-BDT with A=725 nm first absorption peak in solution; FIG. 12F shows UPS spectra of PbS QDs ligand-exchanged with 1,2-BDT with λ=725 nm first absorption peak in solution.

FIG. 13 shows optical absorption spectra of 1,3-BDT-exchanged PbS QDs.

FIG. 14A shows a schematic diagram of modeled PbS(111) slab; FIG. 14B shows plane-averaged electrostatic potentials of (111) slabs with different ligands.

FIG. 15 shows vacuum energy shifts for binding of 1,2-BDT and 1,3-BDT to the PbS(100) surface in various geometries.

FIG. 16A shows DFT simulations of double-sided ligand binding to a PbS(100) slab; FIG. 16B shows transfer curves of PbS QD FETs.

FIG. 17A shows decay in ΔV (where ΔV is the additional V_{OC} induced by the perturbing laser pulse) following turn-off of the perturbation pulse for ZnO/PbS QD NP HJ devices employing EDT, 1,2-BDT, and 1,3-BDT ligand exchange; FIG. 17B shows Extracted recombination rate coefficients k_{rec} for NP HJ photovoltaics across a range of bias light intensities and induced photovoltages.

FIG. 18A shows transient voltage response of a ZnO/PbS QD NP HJ photovoltaic device to a perturbation light pulse under white light bias; FIG. 18B shows transient current response of the same device to the same perturbation pulse without white light bias.

FIG. 19 shows a trap density profile.

FIG. 20A shows current-voltage response of a ZnO/PbS QD rip heterojunction photovoltaic device under illumination with a filtered xenon lamp; FIG. 20B shows external quantum efficiency spectrum of the same device.

### DETAILED DESCRIPTION

The electronic properties of colloidal quantum dots (QDs), also referred to as nanocrystals (NCs), are critically dependent on both QD size and surface chemistry. Modification of quantum confinement provides control of the QD bandgap, while ligand induced surface dipoles present a hitherto-underutilized means of control over the absolute energy levels of QDs within electronic devices. The energy levels of lead sulfide QDs, measured by ultraviolet photoelectron spectroscopy, are shown to shift by up to 0.9 eV between different chemical ligand treatments. The directions of these energy shifts match the results of atomistic density functional theory simulations and scale with the ligand dipole moment Trends in the performance of photovoltaic devices employing ligand-modified QD films are consistent with the measured energy level shifts. These results identify surface-chemistry-mediated energy level shifts as a means of predictably controlling the electronic properties of colloidal QD films and as a versatile adjustable parameter in the performance optimization of QD optoelectronic devices.

A method of improving performance of a photovoltaic device can include modifying a surface energy level of a nanocrystal through ligand exchange. A photovoltaic device can include a layer that includes a nanocrystal with a surface energy modified through ligand exchange.

The electronic properties of coupled colloidal QD solids can be tuned through modification of the QD surface chemistry via ligand exchange. A method of improving performance of a photovoltaic device can include modifying a surface energy level of a nanocrystal through ligand exchange. Modifying surfaces of nanocrystals quantum confinement can control the absolute energy levels of QDs within electronic devices. A wide variety of ligand chemistries can be used, including thiols, primary amines, carboxylic acids, thiocyanate ions, and halide ions.

A photovoltaic device can include a first electrode, a second electrode, charge transporting layers, and an absorptive layer that can include a plurality of semiconductor nanocrystals. A surface of the nanocrystals can be modified through ligand exchange. Modifying surfaces of nanocrystals quantum confinement can control the absolute energy levels of QDs within electronic devices and improve performance of the device. A wide variety of ligand chemistries can be used, including thiols, primary amines, carboxylic acids, thiocyanate ions, and halide ions.

The semiconductor forming the nanocrystals can include a Group II-VI compound, a Group II-V compound, a Group III-VI compound, a Group III-V compound, a Group IV-VI compound, a Group compound, a Group II-IV-VI compound, or a Group II-IV-V compound.

When the electron and hole localize on a nanocrystal, emission can occur at an emission wavelength. The emission has a frequency that corresponds to the band gap of the quantum confined semiconductor material. The band gap is a function of the size of the nanocrystal. Nanocrystals having small diameters can have properties intermediate between molecular and bulk forms of matter. For example, nanocrystals based on semiconductor materials having small diameters can exhibit quantum confinement of both the electron and hole in all three dimensions, which leads to an increase in the effective hand gap of the material with decreasing crystallite size. Consequently, both the optical absorption and emission of nanocrystals shift to the blue, or to higher energies, as the size of the crystallites decreases.

The emission from the nanocrystal can be a narrow Gaussian emission band that can be tuned through the complete wavelength range of the ultraviolet, visible, or infrared regions of the spectrum by varying the size of the nanocrystal, the composition of the nanocrystal, or both. For example, CdSe can be tuned in the visible region and InAs can be tuned in the infrared region. The narrow size distribution of a population of nanocrystals can result in emission of light in a narrow spectral range. The population can be monodisperse and can exhibit less than a 15% rms deviation in diameter of the nanocrystals, preferably less than 10%, more preferably less than 5%. Spectral emissions in a narrow range of no greater than about 75 nm, preferably 60 nm, more preferably 40 nm, and most preferably 30 nm full width at half max (FWHM) for nanocrystals that emit in the visible can be observed. IR-emitting nanocrystals can have a FWHM of no greater than 150 nm, or no greater than 100 nm. Expressed in terms of the energy of the emission, the emission can have a FWHM of no greater than 0.05 eV, or no greater than 0.03 eV. The breadth of the emission decreases as the dispersity of nanocrystal diameters decreases. Semiconductor nanocrystals can have high emission quantum efficiencies such as greater than 10%, 20%, 30%, 40%, 50%, 60%, 70%, or 80%.

The semiconductor forming the nanocrystals can include a Group 11-VI compound, a Group II-V compound, a Group III-VI compound, a Group III-V compound, a Group IV-VI compound, a Group I-III-VI compound, a Group II-IV-VI compound, or a Group II-IV-V compound, for example, ZnO, ZnS, ZnSe, ZnTe, CdO, CdS, CdSe, CdTe, MgO, MgS, MgSe, MgTe, HgO, HgS, HgSe, HgTe, AlN, AlP, AlAs, AlSb, GaN, GaP, GaAs, GaSb, InN, InP, InAs, EnSb, TlN, TlP, TlAs, TlSb, TlSb, PbS, PbSe, PbTe, or mixtures thereof.

Methods of preparing monodisperse semiconductor nanocrystals include pyrolysis of organometallic reagents, such as dimethyl cadmium, injected into a hot, coordinating solvent. This permits discrete nucleation and results in the controlled growth of macroscopic quantities of nanocrystals. Preparation and manipulation of nanocrystals are described, for example, in U.S. Pat. Nos. 6,322,901 and 6,576,291, and U.S. Patent Application No. 60/550,314, each of which is incorporated by reference in its entirety. The method of manufacturing a nanocrystal is a colloidal growth process. Colloidal growth occurs by rapidly injecting an M donor and an X donor into a hot coordinating solvent. The injection produces a nucleus that can be grown in a controlled manner to form a nanocrystal. The reaction mixture can be gently heated to grow and anneal the nanocrystal. Both the average size and the size distribution of the nanocrystals in a sample are dependent on the growth temperature. The growth temperature necessary to maintain steady growth increases with increasing average crystal size. The nanocrystal is a member of a population of nanocrystals. As a result of the discrete nucleation and controlled growth, the population of nanocrystals obtained has a narrow, monodisperse distribution of diameters. The monodisperse distribution of diameters can also be referred to as a size. The process of controlled growth and annealing of the nanocrystals in the coordinating solvent that follows nucleation can also result in uniform surface derivatization and regular core structures. As the size distribution sharpens, the temperature can be raised to maintain steady growth. By adding more M donor or X donor, the growth period can be shortened.

The M donor can be an inorganic compound, an organometallic compound, or elemental metal. M is cadmium, zinc, magnesium, mercury, aluminum, gallium, indium or thallium. The X donor is a compound capable of reacting with the M donor to form a material with the general formula MX. Typically, the X donor is a chalcogenide donor or a pnictide donor, such as a phosphine chalcogenide, a bis(silyl) chalcogenide, dioxygen, an ammonium salt, or a tris(silyl) pnictide. Suitable X donors include dioxygen, bis(trimethylsilyl) selenide ((TMS)₂Se), trialkyl phosphine selenides such as (tri-n-octylphosphine) selenide (TOPSe) or (tri-n-butylphosphine) selenide (TBPSe), trialkyl phosphine tellurides such as (tri-n-octylphosphine) telluride (TOPTe) or hexapropylphosphorustriamide telluride (HPPTTe), bis(trimethylsilyl)telluride ((TMS)₂Te), bis(trimethylsilyl)sulfide ((TMS)₂S), a trialkyl phosphine sulfide such as (tri-n-octylphosphine) sulfide (TOPS), an ammonium salt such as an ammonium halide (e.g., NH₄Cl), tris(trimethylsilyl) phosphide ((TMS)₃P), tris(trimethylsilyl) arsenide ((TMS)₃As), or tris(trimethylsilyl) antimonide ((TMS)₃Sb). In certain embodiments, the M donor and the X donor can be moieties within the same molecule.

A coordinating solvent can help control the growth of the nanocrystal. The coordinating solvent is a compound having a donor lone pair that, for example, has a lone electron pair available to coordinate to a surface of the growing nanocrystal. Solvent coordination can stabilize the growing nanocrystal. Typical coordinating solvents include alkyl phosphines, alkyl phosphine oxides, alkyl phosphonic acids, or alkyl phosphinic acids, however, other coordinating solvents, such as pyridines, furans, and amines may also be suitable for the nanocrystal production. Examples of suitable coordinating solvents include pyridine, tri-n-octyl phosphine (TOP), tri-n-ocryl phosphine oxide (TOPO) and tris-hydroxylpropylphosphine (tHPP). Technical grade TOPO can be used.

Size distribution during the growth stage of the reaction can be estimated by monitoring the absorption line widths of the particles. Modification of the reaction temperature in response to changes in the absorption spectrum of the particles allows the maintenance of a sharp particle size distribution during growth. Reactants can be added to the nucleation solution during crystal growth to grow larger crystals. By stopping growth at a particular nanocrystal average diameter and choosing the proper composition of the semiconducting material, the emission spectra of the nanocrystals can be tuned continuously over the wavelength range of 300 nm to 5 microns, or from 400 nm to 800 nm for CdSe and CdTe. The nanocrystal has a diameter of less than 150 Å. A population of nanocrystals has average diameters in the range of 15 Å to 125 Å.

The nanocrystal can be a member of a population of nanocrystals having a narrow size distribution. The nanocrystal can be a sphere, rod, disk, or other shape. The nanocrystal can include a core of a semiconductor material. The nanocrystal can include a core having the formula MX, where M is cadmium, zinc, magnesium, mercury, aluminum, gallium, indium, thallium, or mixtures thereof, and X is oxygen, sulfur, selenium, tellurium, nitrogen, phosphorus, arsenic, antimony, or mixtures thereof.

The core can have an overcoating on a surface of the core. The overcoating can be a semiconductor material having a composition different from the composition of the core. The overcoat of a semiconductor material on a surface of the nanocrystal can include a Group II-VI compound, a Group II-V compound, a Group III-VI compound, a Group III-V compound, a Group IV-VI compound, a Group compound, a Group II-IV-VI compound, and a Group II-IV-V compound, for example, ZnO, ZnS, ZnSe, ZnTe, CdO, CdS, CdSe, CdTe, MgO, MgS, MgSe, MgTe, HgO, HgS, HgSe, HgTe, AlN, AlP, AlAs, AlSb, GaN, GaP, GaAs, GaSb, InN, InP, InAs, InSb, TIN, TIP, TlAs, TlSb, TlSb, PbS, PbSe, PbTe or mixtures thereof. For example, ZnS, ZnSe or CdS overcoatings can be grown on CdSe or CdTe nanocrystals. An overcoating process is described, for example, in U.S. Pat. No. 6,322,901. By adjusting the temperature of the reaction mixture during overcoating and monitoring the absorption spectrum of the core, over coated materials having high emission quantum efficiencies and narrow size distributions can be obtained. The overcoating can be between 1 and 10 monolayers thick.

The particle size distribution can be further refined by size selective precipitation with a poor solvent for the nanocrystals, such as methanol/butanol as described in U.S. Pat. No. 6,322,901, For example, nanocrystals can be dispersed in a solution of 10% butanol in hexane. Methanol can be added dropwise to this stirring solution until opalescence persists. Separation of supernatant and flocculate by centrifugation produces a precipitate enriched with the largest crystallites in the sample. This procedure can be repeated until no further sharpening of the optical absorption spectrum is noted. Size-selective precipitation can be carried out in a variety of solvent/nonsolvent pairs, including pyridine/hexane and chloroform/methanol. The size-selected nanocrystal population can have no more than a 15% rms deviation from mean diameter, preferably 10% rms deviation or less, and more preferably 5% rms deviation or less.

The outer surface of the nanocrystal can include compounds derived from the coordinating solvent used during the growth process. The surface can be modified by repeated exposure to an excess of a competing coordinating group. For example, a dispersion of the capped nanocrystal can be treated with a coordinating organic compound, such as pyridine, to produce crystallites which disperse readily in pyridine, methanol, and aromatics but no longer disperse in aliphatic solvents. Such a surface exchange process can be carried out with any compound capable of coordinating to or bonding with the outer surface of the nanocrystal, including, for example, phosphines, thiols, amines and phosphates. The nanocrystal can be exposed to short chain polymers which exhibit an affinity for the surface and which terminate in a moiety having an affinity for a suspension or dispersion medium. Such affinity improves the stability of the suspension and discourages flocculation of the nanocrystal. Nanocrystal coordinating compounds are described, for example, in U.S. Pat. No. 6,251,303, which is incorporated by reference in its entirety.

More specifically, the coordinating ligand can have the formula:

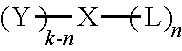

wherein k is 2, 3 or 5, and n is 1, 2, 3, 4 or 5 such that k-n is not less than zero; X is O, S, S═O, SO₂, Se, Se═O, N, N═O, P, P═O, As, or As═O; each of Y and L, independently, is aryl, heteroaryl, or a straight or branched C₂₋₁₂ hydrocarbon chain optionally containing at least one double bond, at least one triple bond, or at least one double bond and one triple bond. The hydrocarbon chain can be optionally substituted with one or more C₁₋₄ alkyl, C₂₋₄ alkenyl, C₂₋₄ alkynyl, C₁₋₄ alkoxy, hydroxyl, halo, amino, nitro, cyano, C₃₋₅ cycloalkyl, 3-5 membered heterocycloalkyl, aryl, heteroaryl, alkylcarbonyloxy, alkyloxycarbonyl, C₁₋₄ alkylcarbonyl, or formyl. The hydrocarbon chain can also be optionally interrupted
by —O—, —S—, —N(R^{a})—, —N(R^{a})—C(O)—O—, —O—C(O)—N(R^{a})—, —N(R^{a})—C(O)—N(R^{b})—, —O—C(O)—O—, —P(R^{a})—, or —P(O)(R^{a})—. Each of R^{a} and R^{b}, independently, is hydrogen, alkyl, alkenyl, alkynyl, alkoxy, hydroxylalkyl, hydroxyl, or haloalkyl.

An aryl group is a substituted or unsubstituted cyclic aromatic group. Examples include phenyl, benzyl, naphthyl, tolyl, anthracyl, nitrophenyl, or halophenyl. A heteroaryl group is an aryl group with one or more heteroatoms in the ring, for instance furyl, pyridyl, pyrrolyl, phenanthryl.

Colloidal quantum dots (QDs) possess a uniquely tunable set of electronic properties that has generated considerable interest in their use as active materials in solution-processed photovoltaics. See, for example, Kim, J. Y. et al., Adv. Mater, 2013, 25, 4986-5010, which is incorporated by reference in its entirety. Synthetic techniques allowing reproducible control of QD size enable the preparation of strongly-confined lead sulfide (PbS) colloidal QDs with bandgaps ranging from 0.7-2.1 eV, spanning the ideal range for single- and multifunction photovoltaic device applications. See, for example, Gao, J. et al., Nano Lett. 2011, 11, 1002-1008, which is incorporated by reference in its entirety. In complement to the control over the QD bandgap afforded by modification of the nanocrystal size, the electronic properties of coupled colloidal QD solids can also be tuned through modification of the QD surface chemistry via ligand exchange. See, for example, Talapin, D. V et al., Science 2005, 310, 86-9, which is incorporated by reference in its entirety. A wide variety of ligand chemistries have been utilized for PbS QDs, the highest-performance QD solar cell material to date, including bidentate aliphatic and aromatic thiols, primary amines, carboxylic acids, thiocyanate ions, and halide ions. For a given ligand, the different facets of the rock-salt-structure PbS nanocrystals present additional differences in steric opportunities and affinities for ligand binding. See, for example, Ip, A. H et al., Nat. Nanotechnol. 2012, 7, 577-82; Klein, E. J. D. et al., Appl. Phys. Lett. 2007, 90, 183113 Pattantyus-Abraham, A. G. et al., ACS Nano 2010, 4, 3374-80; Fafarman, A, T. et al., J. Am, Chem. Soc, 2011, 133, 15753-61; Tang, J. et al., Nat. Mater. 2011, 10, 765-771; Choi, J. J. et al., J. Am, Chem. Soc. 2011, 133, 3131-8, each of which is incorporated by reference in its entirety.

Ligand exchange can influence the carrier mobility by changing the inter-QD dielectric environment and tunneling distance; in the absence of other changes, mobility increases exponentially with decreasing ligand length. See, for example, Liu, Y, et al., Nano Lett. 2010, 10, 1960-9, which is incorporated by reference in its entirety. Appropriate ligands can also passivate electronic trap sites on the QD surface arising from structural aperiodicity and off-stoichiometry of the QD core, increasing carrier and exciton lifetimes and providing a degree of control over the doping level and type of the coupled QD film. See, for example, Voznyy, O. et al. ACS Nano 2012, 6, 8448-8455; Oh, S. J. et al., ACS Nano 2013, 7, 2413-21; Kim, D. et al., Phys. Rev. Lett. 2013, 110, 196802, each of which is incorporated by reference in its entirety. Changing the identity of the chemical binding group and dipole moment of the ligand should also change the strength of the QD-ligand surface dipole, shifting the vacuum energy and, in turn, the QD valence band maximum (VBM) and conduction band minimum (CBM), The surface chemistry of a QD can influence its energy levels; however, most energy-level studies performed on PbS QDs have been performed on QDs with oleic acid ligands that are too insulating for use in photovoltaic devices, or on QDs with a narrow subset of other ligands. See, for example, Soreni-Harari, M. et al., Nano Lett. 2008, 8, 678-84; Timp, B. A. et al., Surf. Sci. 2010, 604, 1335-1341; Jasieniak, J. et al., ACS Nano 2011, 5, 5888-902; Munro, A. M. et al., ACS Appl. Mater. Interfaces 2010, 2, 863-9; Hyun, B.-R. et al., ACS Nano 2008, 2, 2206-12; Gao, J. et al., Nano Lett. 2011, 11, 3263-6; Yuan, M, et al., Adv. Mater. 2013, 25, 5586-92; Katsiev, K. et al., Adv. Mater. 2013, 1-6, each of which is incorporated by reference in its entirety. Given the large shifts in energy levels observed for other species of QDs following ligand exchange, it is unlikely that the energy levels of oleic acid-capped PbS QDs are representative of the energy levels of the ligand-exchanged films used in PbS QD solar cells.

The energy level shifts of PbS QDs treated with twelve different ligands are measured using ultraviolet photoelectron spectroscopy (UPS). The measured valence band maxima span a range of 0.9 eV. Atomistic simulations oldie vacuum energy shift induced by the binding of five of these different ligands to pristine PbS slabs reproduce the observed trend in energy level modification. The impact of these energy level shifts on photovoltaic performance is determined through studies on devices employing 1,2-ethanedithiol (EDT), 1,2-benzenedithiol (1,2-BDT), and 1,3-benzenedithiol (1,3-BUT) ligands. Even between these chemically similar ligands, shifts in the VBM of more than 0.2 eV necessitate ligand-dependent adjustments of the electron- and hole-extracting contacts to achieve optimal performance. These results have recently guided the design and understanding of a certified 8.55% efficient PbS QD solar cell, a current record for this class of devices. See, for example, Chuang, C-H. M. et al., Nat. Mater. 2014, which is incorporated by reference in its entirety. These findings complement the tenability of QD bandgap and highlight an important mechanism of control over the electronic properties of colloidal QDs.

### Ligand-Dependence of QD Energy Levels Measured by UPS

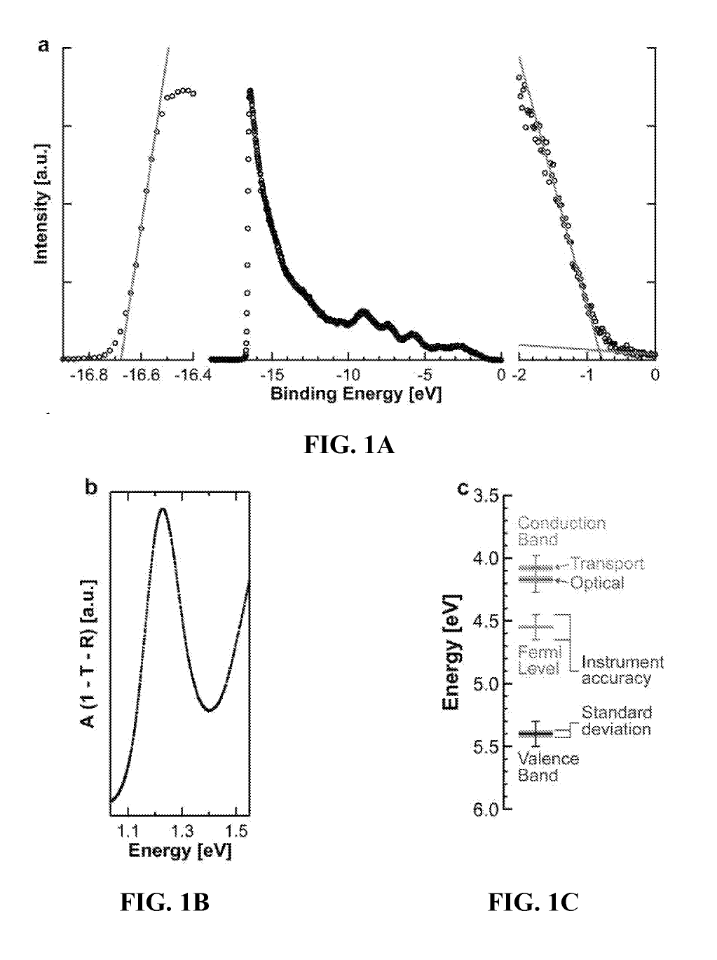

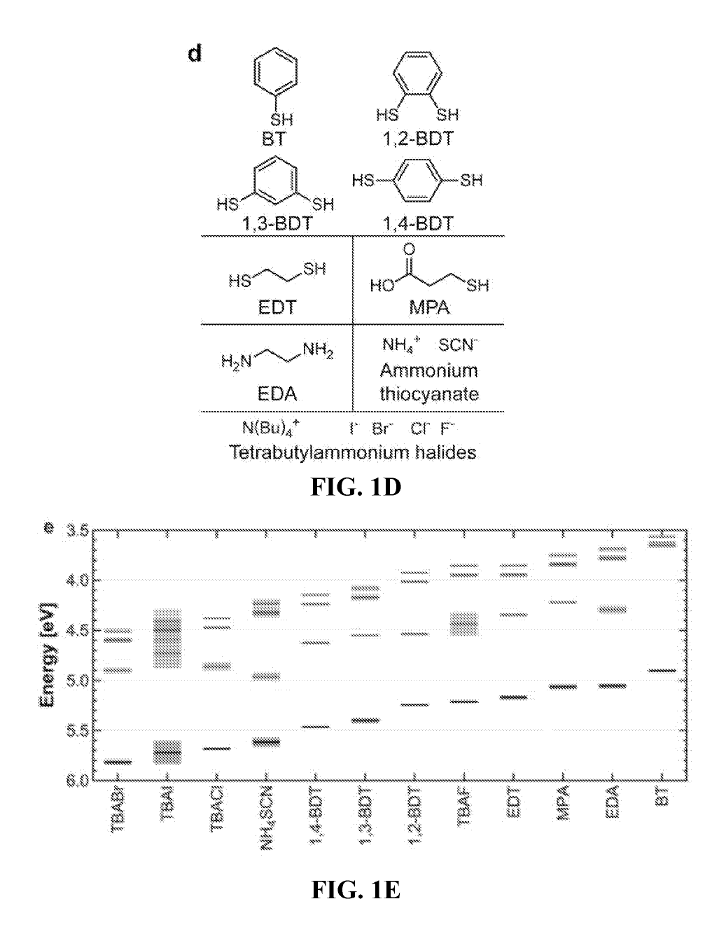

FIG. 1 shows ligand dependent energy levels measured by UPS. FIG. 1A shows the complete ultraviolet photoelectron spectrum of a 100 nm thick 1,3-BDT-exchanged PbS QD film on gold. The left and right side panels display magnified views of the high-binding-energy cutoff (Fermi level) and low-binding-energy cutoff (valence band edge binding energy) regions, respectively, where the band energies are determined from the intersection of a linear extrapolation from the cutoff region to the baseline. FIG. 1B shows optical absorption spectrum (absorption=1 transmission reflection) of the first excitonic peak of 1,3-BDT-exchanged PbS QDs. The peak absorption at E=1.23 eV is taken as the optical bandgap. FIG. 1C shows energy level diagram of 1,3-BDT-exchanged PbS QDs determined from the spectra in A, B and equation (1). Distinction is made between the instrumental accuracy (0.1 eV) and the standard deviation (0.02 eV) across multiple measurements. FIG. 1D shows chemical structures of the ligands employed in this study. FIG. 1E shows complete energy level diagrams of PbS QDs exchanged with the ligands shown in d. All PbS QDs used in this figure have a first excitonic absorption peak at λ=963 nm in solution with native oleic acid ligands. Each data point represents the average of 2-4 measurements across different samples; shaded bars indicate one standard deviation, and error bars for instrument accuracy are omitted for clarity.

FIG. 1A shows a representative UPS spectrum of a 100 nm thick PbS QD film treated with 1,3-BDT without exposure to air. UPS measures occupied electronic states and thus provides information on the Fermi level (low-binding-energy cutoff) and VBM (high-binding-energy-cutoff) of a material. The energy E_{C} of the CBM can be approximated by adding the electronic transport gap E_{g} of the material to the VBM, where E_{g} is determined from the sum of the optical bandgap E_{g}^{opt} and the Coulombic stabilization energy of the confined electron and hole, first derived by Brus using the particle-in-a-box model, such that

$${E}_{c} = {E}_{v} - {E}_{g} = {E}_{v} * {E}_{s}^{opt} - 1.786 \frac{{e}^{2}}{4 π {ɛ}_{0} {ɛ}_{\underline{0} D} R} , \qquad ( 1 )$$

where e is the charge of the electron, ∈₀ is the permittivity of free space, ∈_{QD} is the optical diel5tric constant of the QD core material, and R is the quantum dot radius (determined by matching the first absorption peak in solution to a published sizing curve). See, for example, Brus, L., J. Phys. Chem. 1986, 90, 2555-2560, which is incorporated by reference in its entirety. The PbS QDs used in this study are highly confined, with quantum-confined bandgaps 0.6-1.1 eV larger than the bulk bandgap of PbS. The confined electrons and holes therefore have a high kinetic energy, and the optical dielectric constant (∈_{∞}^{PbS}=17.2) is a more suitable choice than the static dielectric constant (∈₀^{PbS}=169). See, for example, Dalven, R., Solid State Phys. 1974, 28, 179-224, which is incorporated by reference in its entirety.

FIG. 1C shows a representative absorption spectrum of 1,3-BDT-treated PbS QDs on glass. The first absorption peak of the solid-state ligand-exchanged QDs is at energy E_{g}^{opt}=1.23 eV, corresponding to a transport bandgap of E_{g}=1.32 eV. FIG. 1C summarizes the energies of the VBM, Fermi level, and CBM determined from the measurements in FIGS. 1A and 1B for 1,3-BDT-treated PbS QDs. While the instrumental accuracy of UPS is ˜0.1 eV, the standard deviation of the measurement (here across 4 different samples) is much smaller, in the range of 0.02 eV. See, for example, Hwang, J. et al. Mater. Sci. Eng. R Reports 2009, 64, 1-31, which is incorporated by reference in its entirety.

FIG. 1D shows the chemical structure of the twelve ligands employed in this study, including thiols [benzenethiol (BT), 1,2-, 1,3-, and 1,4-benzenedithiol (1,2-BDT, 1,3-BUT, and 1,4-BUT), 1,2-ethanedithiol (EDT), and 3-mercaptopropionic acid (MPA)], a primary amine [1,2-ethylenediamine (EDA)], ammonium thiocyanate (SCN), and halides [tetrabutylammonium iodide (TBAI), bromide (TBABr), chloride (TBACl), and fluoride (TBAF)]. FIG. 1E shows the measured energy levels of a single batch of PbS QDs (λ=963 nm absorption peak in solution) exchanged with these different ligands, sorted by decreasing VBM binding energy.

A maximum shift of 0.9 eV in the VBM is observed between QDs treated with TBABr and BT. Even among the chemically similar bidentate thiols, a shift of 0.3 eV is observed between PbS QDs treated with CDT and 1,4-BUT. Similarly large shifts in energy levels have been observed for conductors treated with thin layers of amine-containing polymers. Such large shifts are expected to have considerable influence on the operation of electronic devices fabricated using PbS QDs. These energy levels are characteristic only of the specific size of PbS QDs studied here, and only under air-free fabrication and storage conditions; UPS measurements performed on PbS QD films fabricated in air indicate different values for the Fermi level and VBM. It is also notable that the majority of ligands tested in this study give rise to VBMs significantly deeper than those reported for oleic-acid-capped PbS QDs in the literature (oleic acid ligands are too insulating to be employed in UPS, which requires adequate grounding of the emissive surface to prevent charging-induced shifts in the observed energy levels). This result highlights the importance of performing energy level measurements on QDs in a chemical environment that is as close as possible to the environment present in an operating device, taking into account both the solid-state ligand environment and the history of exposure to air, vacuum, and solvents.

### Ligand Binding Simulations by Density Functional Theory

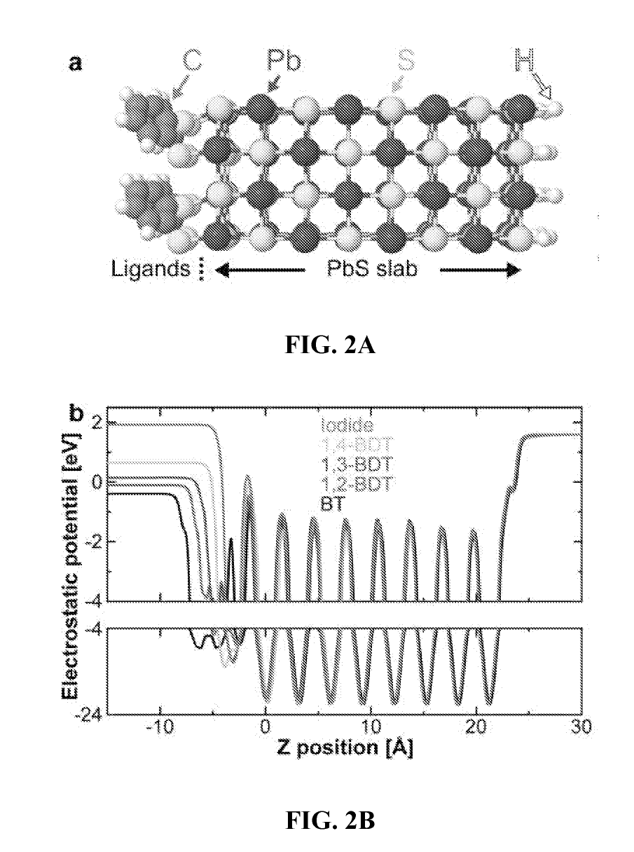

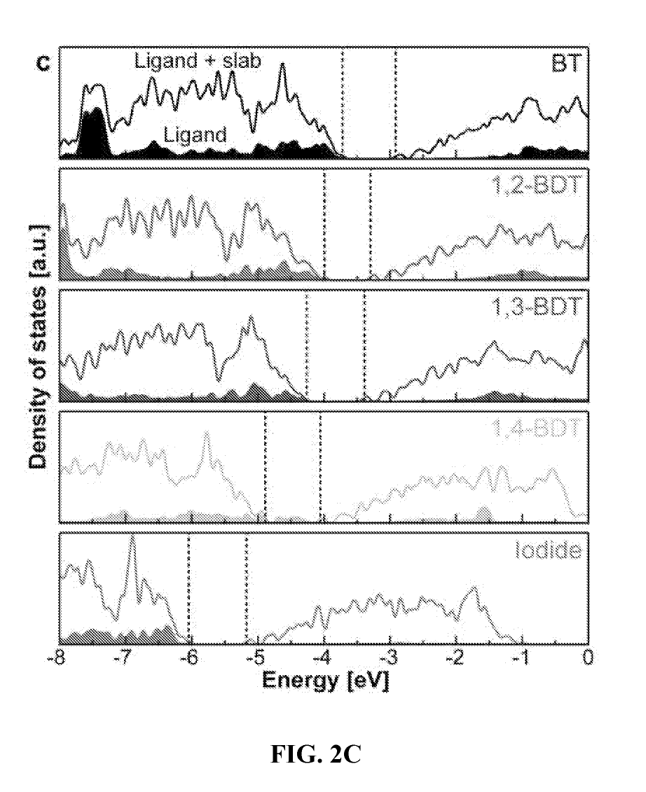

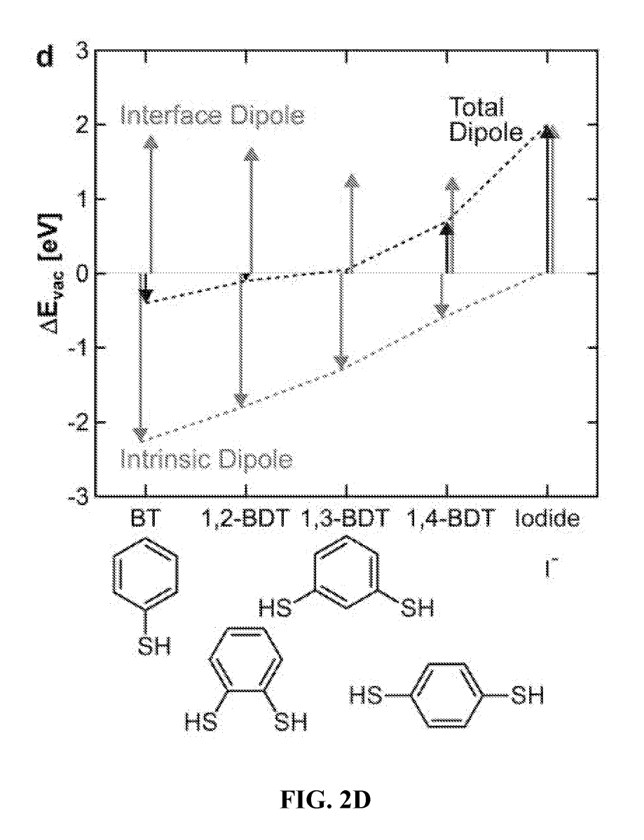

First-principles density functional theory (DFT) calculations provide insight into the origin of the band energy shifts measured by UPS. DFT calculations are widely used to simulate energy level shifts at interfaces between inorganic materials and organic molecules. See, for example, Zhou, Y, et al., Science 2012, 336, 327-32; Heimel, G. et al., Nano Lett. 2007, 7, 932-40; Yang, S. et al., Nano Lett. 2012, 12, 383-8, each of which is incorporated by reference in its entirety. FIG. 2 shows DFT calculations of ligand-induced energy shifts for PbS slabs. FIG. 2A shows a schematic diagram of a modeled PbS slab. The left side of the slab is passivated by adsorbed ligands (1,2-BDT is shown here as an example) and the right side is passivated by appropriate pseudo-hydrogen atoms to ensure charge balance. Monodentate (BT, iodide) and bidentate (1,2-, 1,3-, and 1,4-BDT) ligands are employed here, with ligand density set at one binding atom per surface Pb atom (hence bidentate ligands have half the areal density of monodentate ligands). FIG. 2B shows plane-averaged electrostatic potentials of PbS slabs with different ligands. The potential in the vacuum region far to the left of an unpassivated PbS slab is set to zero. FIG. 2C shows density of states of the ligand (filled curve) and ligand-slab system (unfilled curve) for each of the five ligands considered. The vacuum level above each passivated PbS slab is set to zero. The vertical dashed lines signify the valence and conduction band edge energies. FIG. 2D shows vacuum energy shifts (ΔE_{vac}, black arrows) for each ligand and decomposition into interface (ΔE_{vac,1}, red arrows) and intrinsic ligand (ΔE_{vac,2}, blue arrows) dipoles.

As shown in FIG. 2A, the surface of a PbS QD is approximated as a semi-infinite PbS (100) slab, as the (100) and (111) facets can be dominant for PbS QDs (similar trends in DFT results are obtained for binding to Pb-rich (111) facets). See, for example, Cho, K.-S. et al., J. Am. Chem. Soc. 2005, 127, 7140-7; Bealing, C. R. et al., ACS Nano 2012, 6, 2118-27, each of which is incorporated by reference in its entirety. Modeling the QD surface as a semi-infinite quasi-two-dimensional slab is much more computationally efficient than modeling the entire three-dimensional QD/ligand system, and the electrostatic environment encountered by the electron or hole during transfer across the QD/ligand interface should be similar in both cases. A small dependence on the magnitude of the ligand-induced shift on QD size has been observed elsewhere for InAs QDs, but the direction of the trend in energy levels for different ligands is expected to be independent of QD size. As shown in FIG. 2A, one side of the slab is passivated by ligands and one side by pseudo-hydrogen atoms for charge balance. Similar results are obtained when both sides of the slab are passivated by ligands.

Five of the ligands employed above are simulated by DFT (BT, 1,2-BDT, 1,3-BDT, 1,4-BDT, and iodide), with the ligand coverage held constant at one ligand binding group per surface Pb atom (thus BT and iodide have twice the density of the benzenedithiols). The ligands tested here can efficiently displace the original oleic acid ligands, but it is possible that some oleic acid remains bound to the QD surface, perhaps as a result of variations in binding affinity between the (100) and (111) facets. See, for example, Luther, J. M. et al., ACS Nano 2008, 2, 271-80; Tang, J. et al., ACS Nano 2010, 4, 869-78; Koh; W.-K. et al., Nano Lett. 2011, 11, 4764-7; Law, M. et al., J. Am. Chem. Soc. 2008, 130, 5974-85; Yaacobi-Gross, N. et al, Combining Ligand-Induced Quantum-Confined Stark. Effect with Type 11 Heterojunction Bilayer Structure in CdTe. 2012; Yaacobi-Gross, N. et al., Nat. Mater. 2011, 10, 974-9, each of which is incorporated by reference in its entirety. To facilitate comparison between the different ligands and simplify the OFT simulations, complete exchange of oleic acid is assumed.

FIG. 2B shows the plane-averaged electrostatic potentials for these five ligands bound to PbS (100) slabs. Large shifts in vacuum energy level (ΔE_{vac}) compared to the unpassivated PbS slab are observed. FIG. 2C shows the electronic density of states of the ligand (filled curve) and ligand-slab system (unfilled curve) for each of the five ligands. The PbS bandgap remains relatively unchanged upon ligand adsorption, while the VBM and CRM shifts match the ΔE_{vac} observed in FIG. 2B, indicating that the band edge shifts are electrostatic in origin. There is excellent agreement in the direction and ordering of band edge shifts observed by UPS and DFT, although the magnitude of the shifts is overestimated by DFT.

Shifts in the energy levels of QDs upon ligand adsorption can be conceptualized as the sum of two dipole contributions: a contribution from the dipole formed between the surface atom of the QD and the binding group of the ligand (here referred to as μ₁), and a contribution from the intrinsic dipole moment of the ligand itself (μ₂). For the Lewis-basic ligands studied here, μ₁ points from the negatively-charged ligand to the positively-charged lead atom; μ₂ depends on the chemical structure and binding orientation of the ligand. The z-component of the total dipole (μ_{total,z}) can be expressed as μ_{total,z}=μ_{1.z}+μ_{2.z}, to which ΔE_{vac} is related through the Helmholtz equation:

$$Δ {E}_{vac} = - \frac{{μ}_{total , z}}{A {ɛ}_{r} {ɛ}_{0}} = - ( \frac{{μ}_{1 , z}}{A {ɛ}_{r} {ɛ}_{0}} + \frac{{μ}_{2 , z}}{A {ɛ}_{r} {ɛ}_{0}} ) = Δ {E}_{vac , 1} + Δ {E}_{vac , 2} , \qquad ( 2 )$$

where A is the surface area of the ligand and ∈ᵣ is the dielectric constant of the ligand layer. See, for example, Zehner, R. W. et al, Langmuir 1999, 15, 1121-4127; Alloway, D. M. et al., J. Phys. Chem. B 2003, 107, 11690-11699; Boer, B. de et al., Adv. Maier 2005, 17, 621-625, each of which is incorporated by reference in its entirety.

FIG. 2D shows ΔE_{vac} for each ligand and the decomposition of ΔE_{vac} into the opposing ΔE_{vac,1} and ΔE_{vac,2} terms. The ligand-intrinsic ΔE_{vac,2} terms follow trends predicted by simple electrostatics: iodide lacks an intrinsic dipole, while ΔE_{vac,2} for the thiols increases as the angle between C—S bonds decreases. The interfacial ΔE_{vac,1} term is large for the compact iodide and BT ligands and decreases for more sterically bulky ligands. The trend in ΔE_{vac} is dominated by the influence of the ligand dipole moment rather than the interfacial dipole, as ΔE_{vac} increases monotonically with decreasing |ΔE_{vac,2}|. The lack of an intrinsic dipole moment in opposition to the surface-ligand dipole moment is a general feature of the halide ligands and explains the large band energy shifts observed for this class of ligands in FIG. 1E, The excellent agreement across multiple ligand classes with the trends observed in FIG. 1E lends support both to the use of UPS to reliably measure QD energy levels and to the intuitive description of energy level shifts presented here.

### Ligand-Dependent Photovoltaic Performance

To determine the importance of these shifts in QD energy levels for photovoltaic devices, PbS QDs exchanged with EDT, 1,2-BDT, and 1,3-BDT are incorporated into ZnO/PbS QD np heterojunction, Schottky junction, and donor-acceptor heterojunction photovoltaics. These ligands have been well studied in PbS QD optoelectronic devices to date and employ identical, reproducible ligand-exchange procedures, so they provide an ideal platform for comparison. See, for example, Leschkies, K. S. et al., ACS Nano 2009, 3, 3638-48; Johnston, K. W. et al., Appl. Phys. Lett. 2008, 92, 151115; Zhao, N. et al., ACS Nano 2010, 4, 3743-52; Brown, P. R, et al., Nano Lett. 2011, 11, 2955-61; Jeong, K. S. et al., ACS Nano 2012, 6, 89-99, each of which is incorporated by reference in its entirety. All QD film preparation for the photovoltaics studied here is performed under the same air- and water-free conditions as the film preparation for the UPS studies described above.

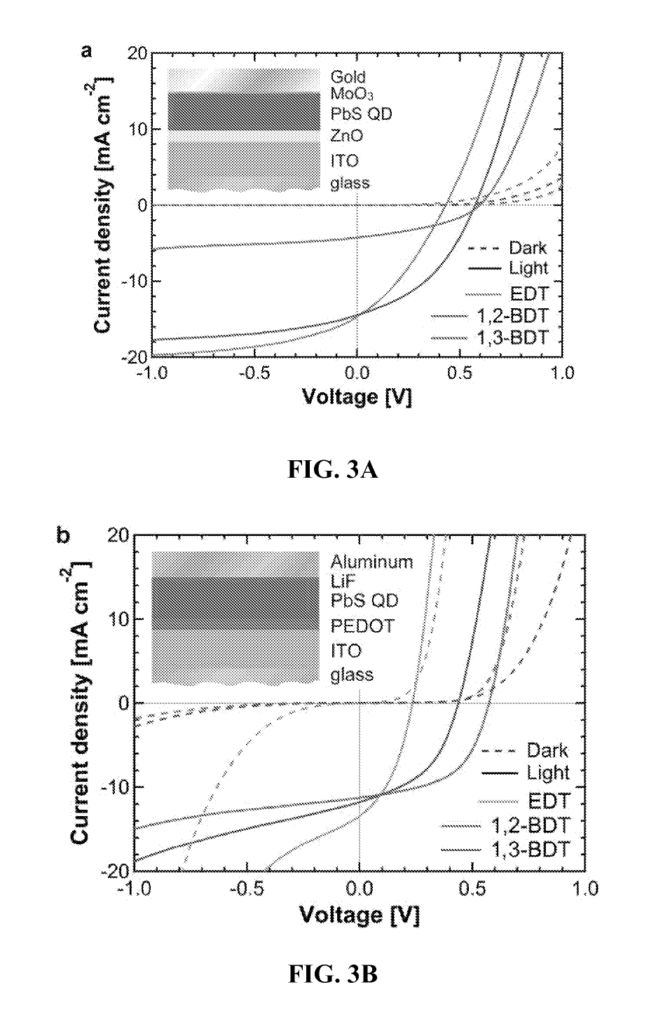

FIG. 3 shows architecture-dependent photovoltaic performance. Current-voltage characteristics measured in the dark (dashed lines) and under 100 mW cm⁻² AM1.5 illumination (solid lines) for EDT-, 1,2-BDT-, and 1,3-BDT-exchanged PbS QDs (λ=905 nm first absorption peak in solution) in FIG. 3A, ZnO/PbS np-heterojunction and FIG. 3B, Schottky junction architectures.

FIG. 3 shows the dark and light J-V characteristics of indium tin oxide (ITO)/ZnO/PbS QD/MoO₃/Au np-heterojunction (np-HJ) photovoltaics (FIG. 3A) and ITO/PEDOT:PSS/PbS QD/LiF/Al Schottky junction (SJ) photovoltaics (FIG. 3B) fabricated with EDT-, 1,2-BDT, and 1,3-BDT-exchanged PbS QD (λ=905 nm first absorption peak in solution) films. Two general performance trends are apparent. First, EDT treatment results in a lower open-circuit voltage (V_{OC}) than 1,2-BDT and 1,3-BDT treatments in both the np-HJ and SJ architectures. Second, the relative performance of 1,2-BDT and 1,3-BDT-exchanged QDs is reversed between the np-HJ and SJ architectures: 1,3-BDT exchange results in the best performance for the np-HJ architecture, while 1,2-BDT exchange results in the best performance for the SJ architecture. A straightforward comparison of trap distributions, carrier mobilities, and recombination rates could explain the first of these two trends, but not the second. While EDT treatment leads to the highest carrier mobility of the three ligands studied, the high recombination rate and high trap density of EDT-exchanged PbS QD films lead to a lower V_{OC} and power conversion efficiency (η_{P}) than BDT-exchanged films. However, changes in these properties do not explain the architecture-dependent performance of 1,2-BDT and 1,3-BDT-exchanged QDs. The difference in the energetic environment of the QD film between the np-HJ and SJ architectures suggests that a shift in the energy levels of the PbS QDs between the two different ligand treatments could explain this difference in performance.

By focusing on the SJ architecture, the interfacial energetics can be tuned in a controlled manner through modification of the electron- and hole-extracting contacts. A modification to the simple ITO/PbS/cathode structure is to insert a layer of PEDOT:PSS as a hole-extracting layer between the ITO and the PbS QDs, See, for example, Ma, W. et al., 2011, 8140-8147; Choi, J. J. et al., Nano Lett 2009, 9, 3749-55, each of which is incorporated by reference in its entirety. PEDOT:PSS can aid in hole injection into, and hole extraction out of, organic semiconductors with deep highest occupied molecular orbitals (HOMOs) as a result of its deep work function (E_{F}=5.0 eV for PEDOT:PSS, vs. 4.7 eV for ITO). See, for example, Koch, N. et al., Appl. Phys. Lett. 2003, 82, 70; Milliron, D. J. et al., J. Appl. Phys. 2000, 87, 572, each of which is incorporated by reference in its entirety.

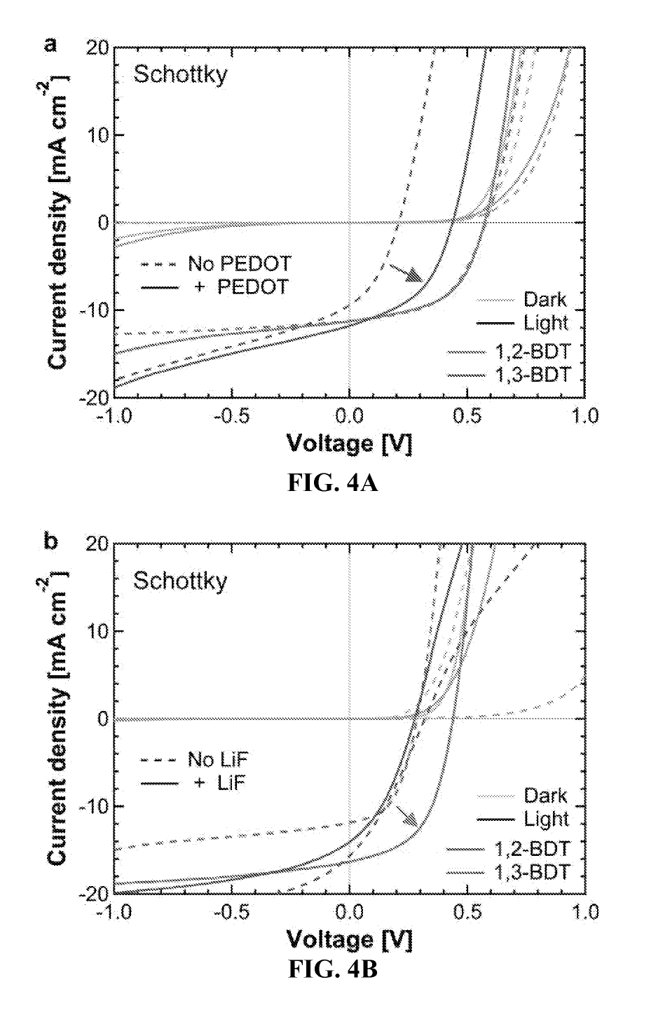

FIG. 4 shows ligand-induced changes in Schottky photovoltaic performance. FIG. 4 depicts current-voltage characteristics of Schottky junction photovoltaics employing 1,2-BDT (red traces) and 1,3-BDT (blue traces) showing the influence of a PEDOT:PSS hole transport layer (FIG. 4A) and a LiF cathode interlayer (FIG. 4B). In each case the interlayer significantly improves the performance of only one of the two ligands, in a manner in keeping with the results of FIG. 1. In FIG. 4A, it is observed that the inclusion of a PEDOT:PSS hole-extracting layer results in a 3.2-fold improvement in η_{P} for a SJ photovoltaic fabricated with 1,3-BDT-exchanged PbS QDs, while it has a negligible effect on a 1,2-BDT-exchanged Si photovoltaic. This observation matches what would be expected from the energy levels reported in FIG. 1E: 1,3-BDT-treated QDs, with their deeper VBM, benefit more from the high-work-function PEDOT:PSS hole transport layer than do the 1,2-BDT-treated QDs.

Similarly, a thin layer of LiF can be inserted between the cathode and the electron transport layer in organic LEDs and solar cells, where it is shown to increase the efficiency of electron injection and extraction, See, for example, Shaheen, S. E. et al., J. Appl. Phys, 1998, 84, 2324: Tang, J. et al., Adv. Mater. 2010, 22, 1398-402, each of which is incorporated by reference in its entirety. This effect can be attributed to a lowering of the effective cathode work function as a result of a strong interface dipole induced by the LiF, resulting in a reduced barrier height for electron injection. See, for example, Brabec, C. J. et al., Appl. Phys. Lett. 2002, 80, 1288, which is incorporated by reference in its entirety. In the PbS QD SJ architecture described here, a reduction in the cathode work function should result in a greater benefit for PbS QDs with a shallower VBM and CBM by strengthening the Schottky junction at the interface and increasing the driving force for electron extraction. Indeed, it is observed in FIG. 4B that the insertion of LiF results in a 2.2-fold improvement in η_{P} for 1,2-BDT-treated QDs while having a negligible effect on the η_{P} of 1,3-BDT-treated QDs, which is consistent with the shallower energy levels reported in FIG. 1E for 1,2-BDT-treated PbS QDs.

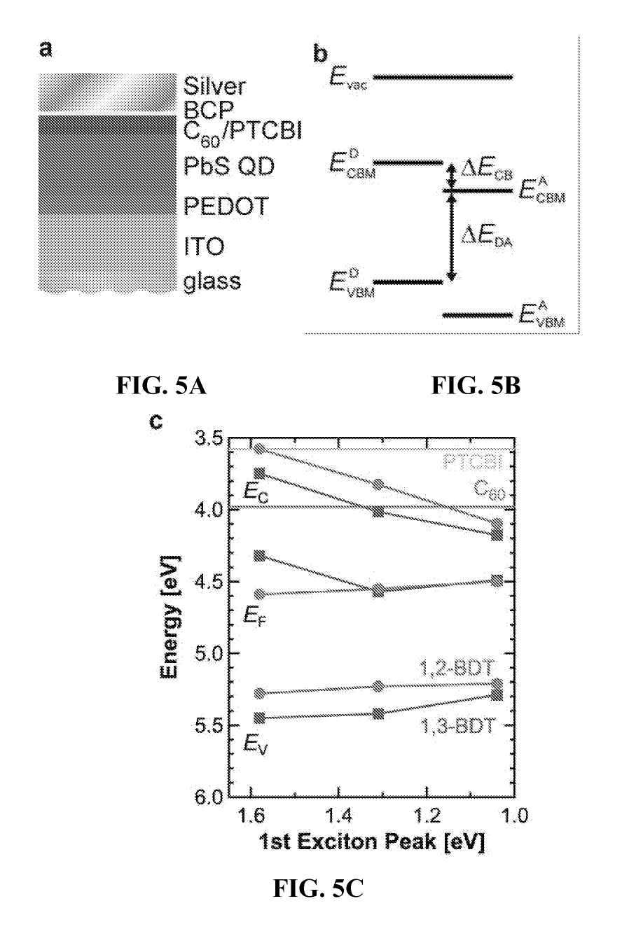

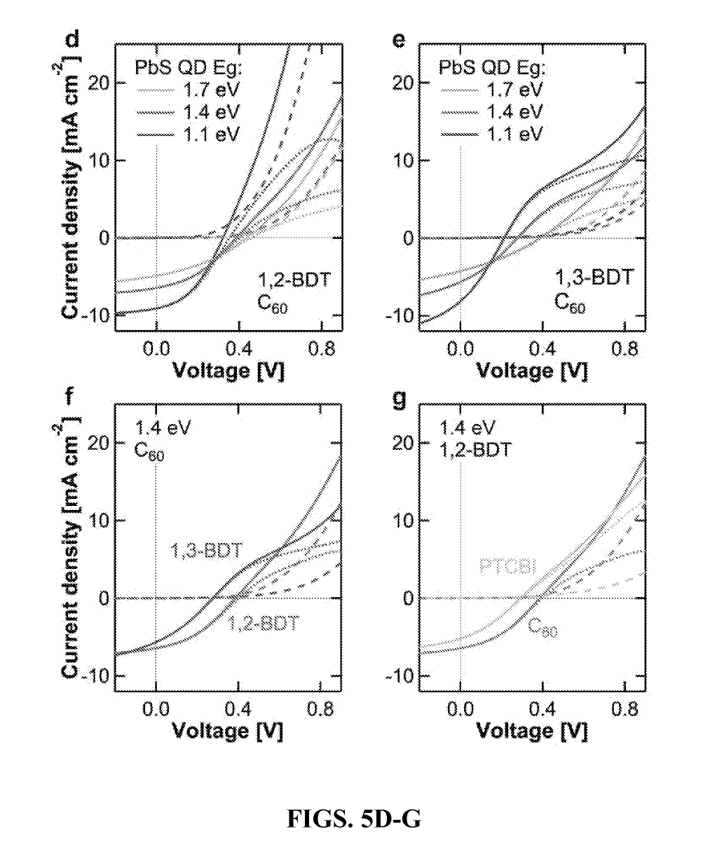

The donor-acceptor heterojunction (DA-HJ) is an alternative to the SJ architecture that relies directly on the band offsets at the D-A interface (rather than on Schottky barrier formation, which can be sensitive to surface traps and other complications) to separate charge carriers, thus providing an architecture wherein the interfacial energy level alignment can be probed more directly. See, for example, Luther, J. M. et al., Nano Lett. 2008, 8, 3488-92, which is incorporated by reference in its entirety. FIG. 5 shows ligand- and QD-size-induced changes in DA-HJ photovoltaic performance, FIG. 5A shows device structure of the donor-acceptor heterojunction and FIG. 5B shows schematic band diagram of the donor-acceptor pair, showing a conduction band offset ΔE_{CB} that is favorable for photocurrent extraction. FIG. 5C shows measured energy levels of three different sizes of PbS QDs, with LUMO energies of C₆₀ and PTCBI from the literature. The conduction band energy E_{C} corresponds to the transport gap; the optical gap is omitted here for clarity. The experimental uncertainty of the QD energy levels determined by UPS is 0.1 eV; the uncertainty of the LUMOs of the organic materials determined by inverse photoelectron spectroscopy in the literature is 0.5 eV. FIGS. 5D-5G show dark current (dashed curves), light current (solid curves), and photocurrent (dotted curves) of DA-HJ photovoltaics, comparing FIG. 5D, 1,2-BDT-treated QDs of different size paired with C₆₀, FIG. 5E, 1,3-BDT-treated QDs of different sizes paired with C₆₀, FIG. 5F, 1,2-BDT and 1,3-BDT-treated QDs of a given size paired with C₆₀, and FIG. 5G, 1,2-BDT-treated QDs paired with PTCBI and C₆₀.

FIG. 5A displays a DA-HJ device architecture in which PbS QDs act as the electron donor and either buckminsterfullerene (C₆₀) or 3,4,9,10 perylenetetracarboxylic bisbenzimidazole (PTCBI) act as the electron acceptor. FIG. 5B displays an outline of the energy level structure in a DA-HJ photovoltaic device. An important design criterion for the DA-HJ is that ΔF_{CB}, given by ΔE_{CB}=E_{CBM}^{D}−E_{CBM}^{A}, must be positive and sufficiently large to allow transfer of photogenerated electrons from the CBM of the donor to the lowest unoccupied molecular orbital (LUMO) of the acceptor. A large, positive ΔE_{CB} should also prevent unwanted back-transfer of photogenerated electrons from the acceptor to the donor. Thus, by modifying ΔE_{CB} and observing the performance of the resultant DA-HJ photovoltaic device, shifts in the energy levels of the PbS QDs can be inferred and compared to those determined by UPS.

FIG. 5C shows the measured energy levels of three different sizes of PbS QDs (λ=725 nm, 905 nm, and 1153 nm first absorption peaks in solution) after ligand exchange with 1,2-BDT or 1,3-BDT. The CBM is found to change more with QD size than the VBM, as has been noted previously in the literature. The LUMOs of C₆₀ and PTCBI are taken from inverse photoelectron spectroscopy measurements reported in the literature to be 4.0±0.5 eV and 3.6±0.5 eV, respectively, FIGS. 5D-5G show the dark current, light current, and photocurrent J-V responses (J_{dark}, J_{light}, and J_{pc}, respectively, where J_{pc}=J_{light}−J_{dark}) or DA-HJ photovoltaics pairing these three different sizes of 1,2-BDT- and 1,3-BDT-exchanged PbS QDs with C₆₀ and PTCBI.

As the bandgap of the 1,2-BDT-exchanged QDs is reduced, the reduced capacity for quasi-Fermi level splitting leads to a smaller V_{OC}, but the increased absorption at longer wavelengths leads to a higher J_{SC} (FIG. 5D). This same trend is observed for 1,3-BDT-exchanged QDs (FIG. 5E), but the diode properties for 1,3-BDT deviate substantially from ideal behavior. As the bandgap decreases and the CBM moves to deeper energies, J_{light} crosses J_{dark} at smaller voltages and a “kink” in the forward-bias J_{light} becomes more pronounced, corresponding to a reversal in the polarity of J_{pc} as the short circuit current (negative polarity) is subsumed by an increased photoconductivity (positive polarity), This increase in photoconductivity in forward bias is expected if the ΔE_{CB} at the donor-acceptor interface is made less positive, corresponding to a deepening of the donor CBM, as the barrier to electron transfer from acceptor to donor is reduced.

Similar trends are observed in FIG. 5F, g when comparing the performance of PTCBI and C₆₀ as acceptors and that of 1,2-BDT-exchanged QDs and 1,3-BDT-exchanged QDs as donors. The LUMO of PTCBI is ˜0.4 eV shallower in energy than that of C₆₀, leading to a reduction in ΔE_{CB}; correspondingly, the DA-HJ employing PTCBI demonstrates a greater contribution from photoconductive back-electron transfer in the form of a lower-voltage J_{light}-J_{dark} crossover. Similarly, from FIG. 5C, the measured CBM of 1,3-BDT-exchanged 1.1 eV PbS QDs is 0.2 eV deeper than that of 1,2-BDT-exchanged PbS QDs of the same size, which also leads to a reduction in ΔE_{CB}; as such, J_{light}, for 1,3-BDT demonstrates a stronger forward-bias “kink” and a lower-voltage crossover with J_{dark}.

Taken together, FIGS. 5D-5G show that the substitution of 1,3-EDT for 1,2-BDT (which, from the energy level measurements reported here, results in a 0.1-0.2 eV deeper CBM) induces changes in DA-HJ photovoltaic performance that are qualitatively similar to those induced by reducing the bandgap of the QD or by substituting PTCBI for C₆₀, both of which can result in a reduction in ΔE_{CB}. This observation provides support for the method of energy level measurement reported here and for the use of these energy levels in describing the performance of PbS QD optoelectronic devices.

The band energies of colloidal QDs can be modified by ligand exchange, resulting in energy level shifts of up to 0.9 eV for PbS QDs. Trends in energy level position between different ligands are confirmed by atomistic modeling, showing that the observed shifts result from contributions from both the QD-ligand interface dipole and the intrinsic dipole moment of the ligand molecule itself. These energy level shifts result in predictable changes in photovoltaic device operation and provide a guide to the optimal ligand choice and device architecture for QD photovoltaics. These can guide the design of a current-record-efficiency PbS QD photovoltaic device employing a cascaded energy level architecture. These results identify ligand-induced hand-energy shifts, in complement to quantum confinement-controlled bandgap modification, as a means of predictably controlling the electronic properties of colloidal QDs and as a critical adjustable parameter in the optimization of QD optoelectronic devices.

A photovoltaic device can include a first electrode; a first charge transporting layer in contact with the first electrode; a second electrode; a second charge transporting layer in contact with the second electrode; and a plurality of semiconductor nanocrystals disposed between the first charge transporting layer and the second charge transporting layer, wherein a surface of the plurality of semiconductor nanocrystals is modified through ligand exchange.

The first charge transporting layer can include a first inorganic material. The first inorganic material can be amorphous or polycrystalline. The first inorganic material can be an inorganic semiconductor. The inorganic semiconductor can include a metal chalcogenide. The metal chalcogenide can be a mixed metal chalcogenide. The metal chalcogenide can include a zinc oxide, a titanium oxide, a niobium oxide, a zinc sulfide, an indium tin oxide, or a mixture thereof.

The second charge transporting layer can include a second inorganic material. The second inorganic material can be amorphous or polycrystalline. The second inorganic material can be an inorganic semiconductor. The inorganic semiconductor can include a metal chalcogenide. The metal chalcogenide can be a mixed metal chalcogenide. The metal chalcogenide can include a zinc oxide, a titanium oxide, a niobium oxide, a zinc sulfide, an indium tin oxide, a molybdenum oxide, or a mixture thereof.

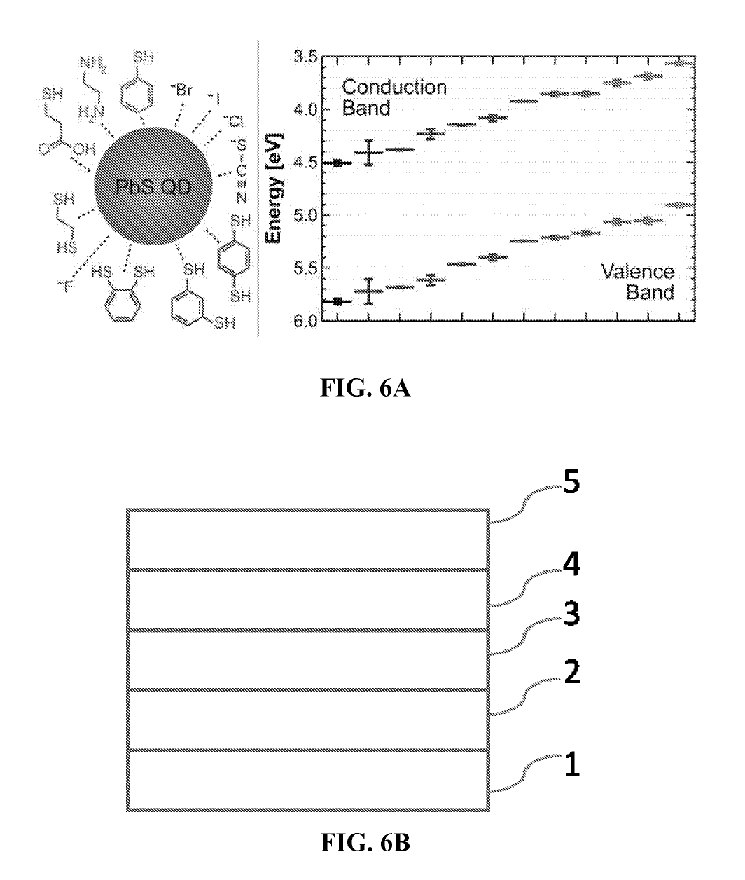

A photovoltaic device can have a structure such as shown in FIG. 6B, in which a first electrode 2, a first layer 3 in contact with the electrode 2, a second layer 4 in contact with the layer 3, and a second electrode 5 in contact with the second layer 4. First layer 3 can be a hole transporting layer and second layer 4 can be an electron transporting layer. At least one layer can be non-polymeric. The layers can include an inorganic material. One of the electrodes of the structure is in contact with a substrate 1. Each electrode can contact a power supply to provide a voltage across the structure. Photocurrent can be produced by the absorptive layer when a voltage of proper polarity and magnitude is applied across the device. First layer 3 can include a plurality of semiconductor nanocrystals, for example, a substantially monodisperse population of nanocrystals, A surface of the nanocrystals can be modified through ligand exchange. A surface of the nanocrystals can be modified through ligand exchange.

Alternatively, a separate absorptive layer (not shown in FIG. 6B) can be included between the hole transporting layer and the electron transporting layer. The separate absorptive layer can include the plurality of nanocrystals. A surface of the nanocrystals can be modified through ligand exchange. A layer that includes nanocrystals can be a monolayer, of nanocrystals, or a multilayer of nanocrystals. In some instances, a layer including nanocrystals can be an incomplete layer, i.e., a layer having regions devoid of material such that layers adjacent to the nanocrystal layer can be in partial contact. The nanocrystals and at least one electrode have a band gap offset sufficient to transfer a charge carrier from the nanocrystals to the first electrode or the second electrode. The charge carrier can be a hole or an electron. The ability of the electrode to transfer a charge carrier permits the photoinduced current to flow in a manner that facilitates photodetection.

### Examples

### PbS QD Synthesis and Film Preparation.

All synthesis, fabrication, and testing is performed under oxygen- and water-free conditions unless otherwise stated. Oleic acid-capped PbS QDs are synthesized via standard literature methods and purified three times by precipitation and centrifugation in a mixture of acetone and 1-butanol, followed by resuspension in hexane. See, for example, Chang, L.-Y, et al., Nano Lett. 2013, 13, 994-9, which is incorporated by reference in its entirety. After the final round of purification, the QDs are dissolved in octane at a concentration of 25 mg mL⁻¹. All solid QD films are prepared by sequential spin-casting. For each layer, 15 μL of QD solution is dispensed through a 0.02 μm filter (Anotop) onto a 12.5 mm×12.5 mm substrate and spin-cast at 1500 rpm for 15 s. Roughly 200 μL of ligand solution is then dispensed through a 0.1 μm filter (PTFE) onto the substrate, allowed to sit for 30 s, and spun dry. The substrate is then flooded with the solvent used for ligand exchange and spun dry three times to remove unbound ligand, and the entire process is repeated; each complete iteration results in the deposition of ˜20 nm of QDs. The ligand concentrations and solvents used in this study are representative of well-characterized ligand exchange conditions from the literature: benzenethiol and 1,2-, 1,3-, and 1,4-benzenedithiol, 1.7 mM in acetonitrile (ACN); 1,2-ethanedithiol, 1.7 mM in ACN; 3-mercaptopropionic acid, 115 mM in methanol (MeOH); ethylenediamine, 1M in MeOH ammonium thiocyanate, 30 mM in MeOH; and tetrabutylammonium fluoride, chloride, bromide, and iodide, 30 mM in MeOH. See, for example, Koleilat, G. I. et al., ACS Nano 2008, 2, 833-40; Talgorn, E. et al., Nat. Nanotechnol. 2011, 6, 733-739; Zhitomirsky, D, et al., N-Type Colloidal-Quantum-Dot Solids for Photovoltaics. 2012, each of which is incorporated by reference in its entirety. All chemicals are purchased from Sigma Aldrich at the highest purity available.

### Ultraviolet Photoelectron Spectroscopy.

UPS spectra are collected using an Omicron ultrahigh vacuum system with a base pressure of 10⁻¹⁰ mbar. The substrates for the UPS measurement are 12.5 mm×12.5 mm glass slides coated with Cr(10 nm)/Au(100 nm) anodes by thermal evaporation and stored in air-free conditions without further surface treatment. Five sequential spin casting cycles of PbS QDs with various ligand treatments, performed as described above, result in a QD film thickness of ˜100 nm. Electrical contact from the steel sample plate to the Cr/Au anode is made using carbon tape. Samples for UPS are transported from an inert-atmosphere glovebox (<1 ppm O₂) to the UPS system without exposure to air using a load-locked transfer system. During the UPS measurement, illumination at 21.22 eV is provided by the He(I) emission line from a Helium discharge lamp, and the chamber pressure increases to 10⁻⁷ mbar. The samples are biased at −5.0 V to ensure accurate determination of the low-kinetic energy cutoff, and electron emission is collected at 0° from normal, Single kinetic energy scans are completed in <45 seconds to minimize charging. Cutoff energies are determined from the intersection of a linear extrapolation of the cutoff region to a linear extrapolation of the baseline.

### Density Functional Theory Calculations.

DFT calculations are performed using the Vienna Ab initio Simulation Packages (VASP) with the generalized gradient approximation of Perdew-Burke-Emzerhof (PBE) for the exchange and correlation functional. See, for example, Kresse, G. et al., Comput. Mater. Sci. 1996, 6, 15-50; Perdew, J. et al., Phys. Rev. Lett. 1996, 77, 3865-3868, each of which is incorporated by reference in its entirety. The projector-augmented-wave method is adopted to describe the core electrons. Recent work has shown that variations in ligand coverage density can significantly affect electronic properties;¹³ surface coverage here is held constant at one binding atom per surface lead atom. An energy cutoff of 400 eV and a Monkhorst-Pack k-point sampling of 5×5×1 are used after extensive convergence analyses. A large vacuum spacing of >20 Å is used to prevent inter-slab interactions. Each (100) PbS slab consists of 8 single layers, and pseudohydrogen atoms with fractional charges of 5/3 and 1/3e are chosen to passivate the surface Pb and S atoms on the back layer. Ligands and the top five layers of the PbS slab are fully relaxed using the conjugate gradient method until the structure satisfies the following relaxation criteria: (i) the energy difference between two consecutive ionic steps is less than 10⁻⁴ eV, and (ii) the maximum Hellmann-Feynman forces acting on each atom are less than 0.02 eV Å⁻¹. Dipole corrections are included to remove the spurious electrostatic interactions between neighboring supercells.

### Photovoltaic Device Fabrication.

Photovoltaic devices are deposited onto ITO-coated glass substrates (Thin Film Devices) that have been cleaned by ultrasonication in micro-90 soap solution, deionized water, acetone, and isopropanol, followed by treatment with ozone plasma. The device area is defined by the anode-cathode overlap to be 1.24 mm². Zinc oxide (Plasmaterials) is deposited by rf-sputtering. Molybdenum oxide (99.9995%), lithium fluoride (99.99%), buckminsterfullerene (C₆₀), 3,4,9,10 perylenetetracarboxylic bisbenzimidazole (PTCBI), bathocuproine (BCP), aluminum, silver, and gold are deposited by thermal evaporation at 0.5-1 Å/s at a base pressure of 10⁻⁶ torr. Polyethylenedioxythiophene-polystyrene sulfonate (PEDOT:PSS, conductive grade, Sigma-Aldrich) is deposited by spin-casting in air at 4000 rpm for 60 s, then annealed at 150° C. inside a nitrogen-atmosphere glovebox for 30 minutes. The ITO-coated glass substrates are soaked overnight in a solution of 12 mM (3-mercaptopropyl)trimethoxysilane (3-MPTMS) in toluene to increase QD adhesion to the substrate, then sonicated for 1 minute in isopropanol to remove unbound 3-MPTMS. Np-heterojunction (np-HJ) photovoltaic devices utilize the architecture ITO/ZnO (50 nm)/PbS QD (160 nm)/MoO₃ (10 nm)/Au (100 nm). Schottky junction photovoltaic devices utilize the architecture ITO/PEDOT:PSS/PbS QD (160 nm)/LiF (0.7 nm)/Al (100 nm) unless otherwise noted. Donor-acceptor photovoltaic devices utilize the architecture ITO/PEDOT:PSS/PbS QD (160 nm)/(C₆₀ or PTCBI) (40 nm)/BCP (10 nm)/Ag (100 nm).

### Electrical Characterization.

Current density-voltage (J-V) curves of photovoltaic devices are recorded using a Keithley 6487 picoarrirneter, and 100 mW cm² illumination is provided by a xenon lamp (Newport 96000) equipped with an AM1.5G filter.

### Ultraviolet Photoelectron Spectra and Absorption Spectra of QD-Ligand Complexes

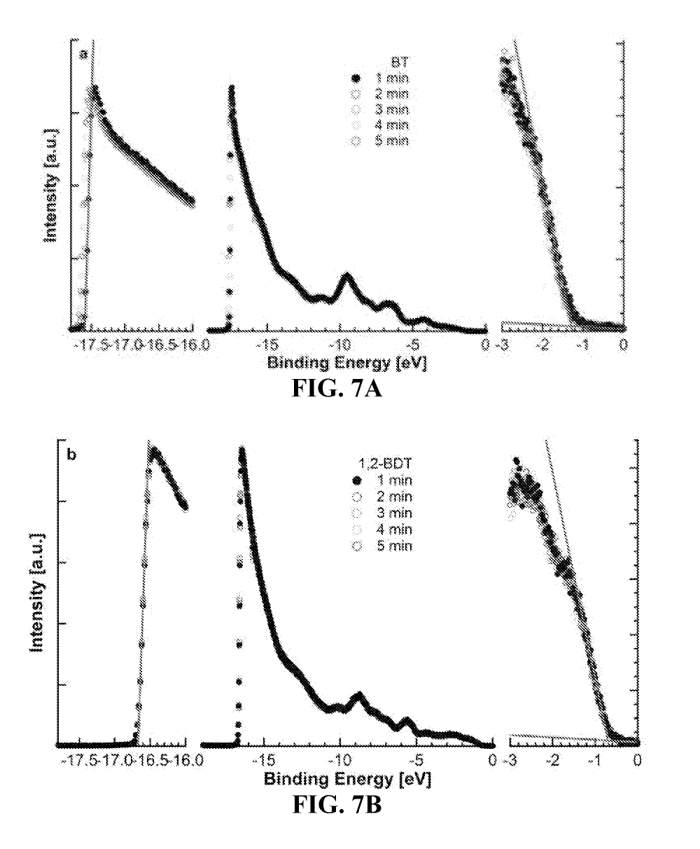

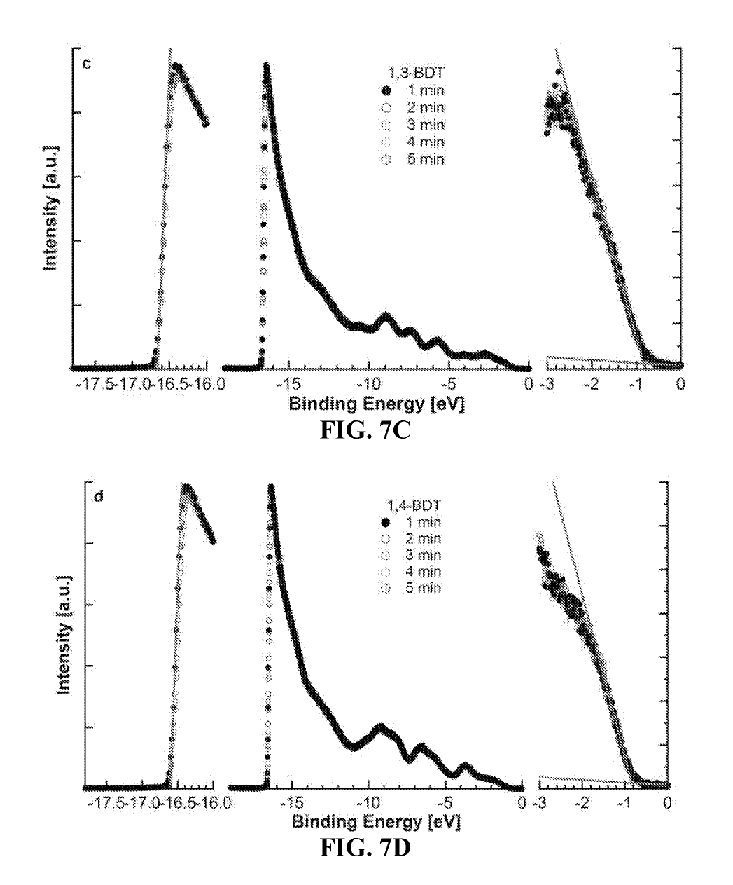

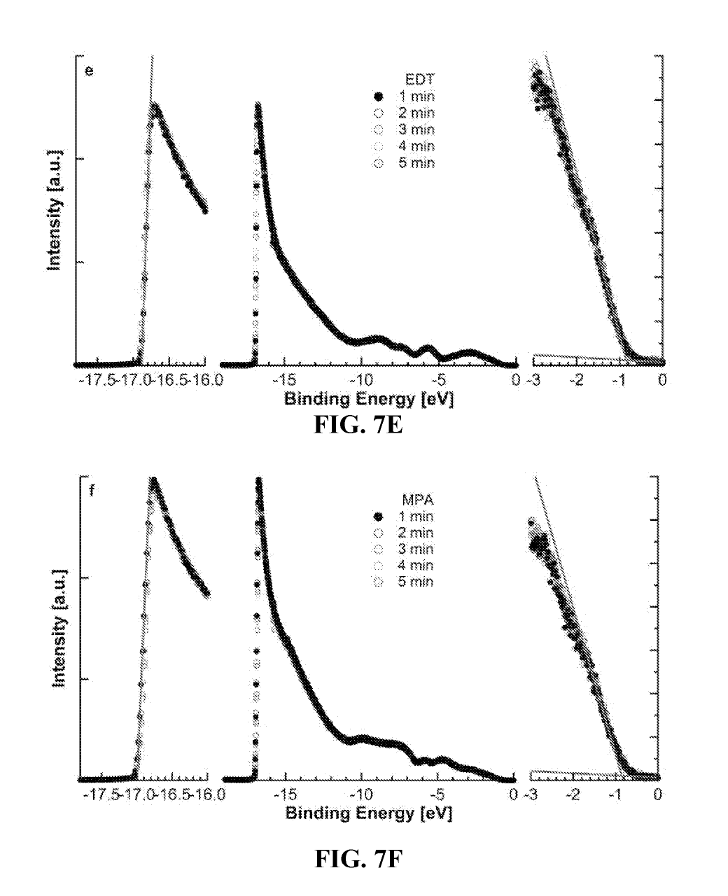

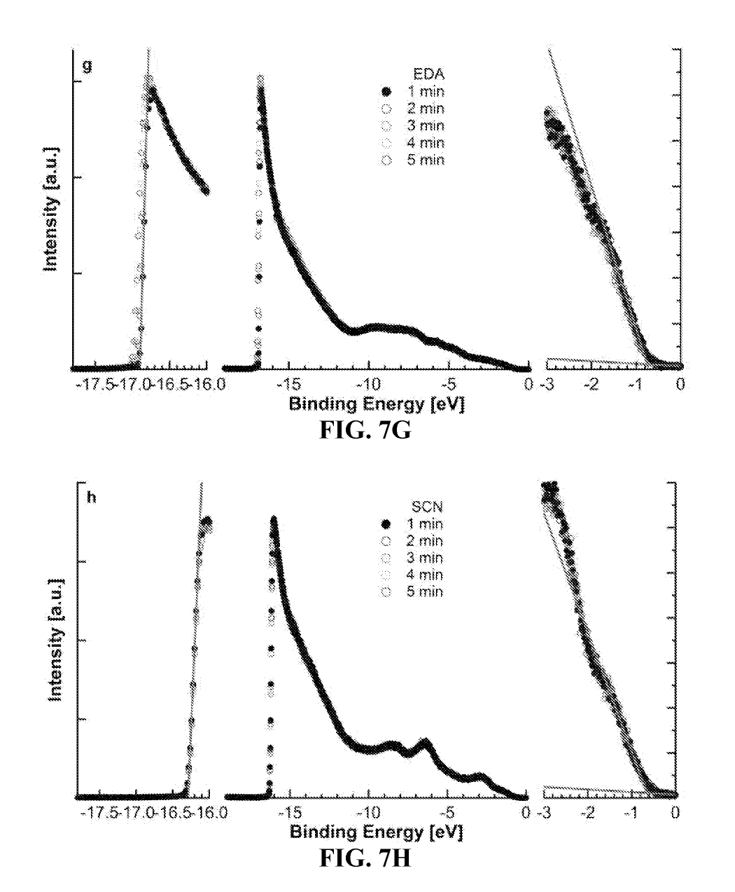

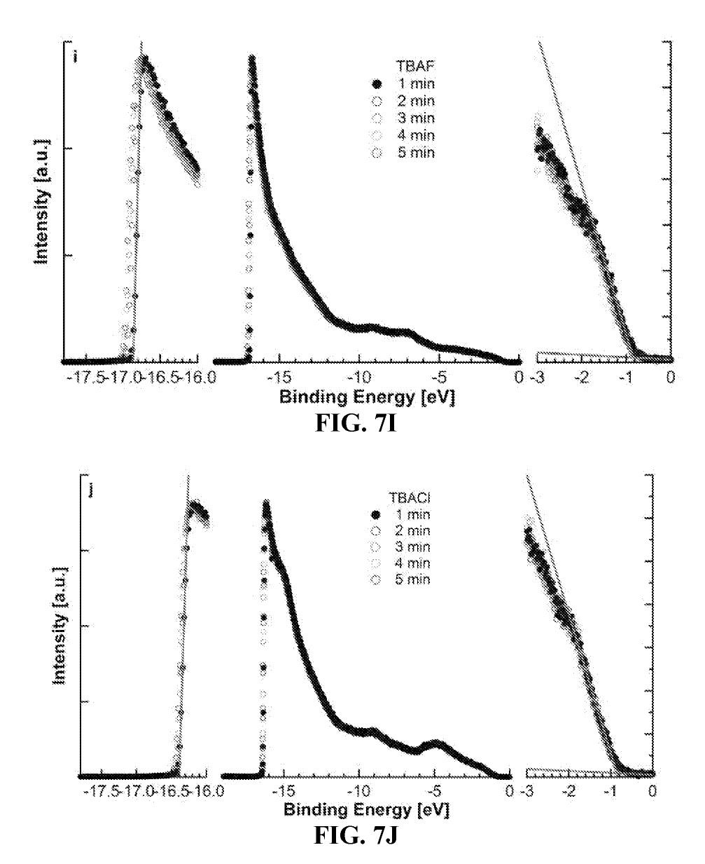

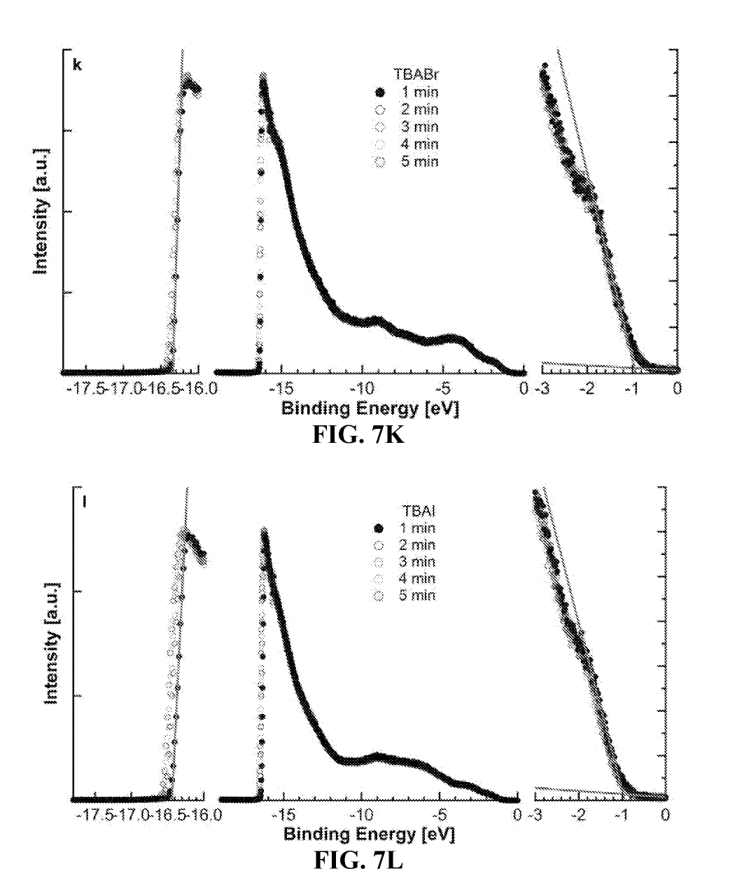

FIG. 7 shows ultraviolet photoelectron spectra of 100 nm thick ligand-exchanged PbS QD films on gold substrates. FIG. 7 shows ultraviolet photoelectron spectra of 100 nm thick ligand-exchanged PbS QD films on gold substrates: A, benzenethiol; B, 1,2-benzenedithiol; C, 1,3-benzenedithiol; D, 1,4-benzenedithiol; E, 1,2-ethanedithiol; F, 3-mercaptopropionic acid; G, ethylenediamine; H, ammonium thiocyanate; 1, tetrabutylammonium fluoride; J, tetrabutylammonium chloride; K, tetrabutylammonium bromide; L, tetrabutylammonium iodide. Five sequential scans collected over five minutes are displayed for each sample. Red lines indicate fits to the first scan (labeled “1 min”). The Fermi energy is determined from the intercept of a linear extrapolation of the secondary electron cutoff region with the x-axis. The valence band binding energy is determined from the intercept of a linear extrapolation of the primary electron cutoff region with a linear extrapolation of the baseline.

FIG. 7 shows representative ultraviolet photoelectron spectra used to determine the energy levels of the ligand-exchanged PbS QDs (λ=963 nm first absorption peak in solution) displayed in FIG. 1, Five sequential scans collected at one-minute intervals are shown for each ligand. For an unchanging sample in equilibrium, the five scans should be identical; if the sample charges over time due to insufficient electrical contact, or if the chemical structure of the sample changes due to interaction with the 21.22 eV photon beam, the spectrum can shift over time. It is observed that the spectra of the thiols are very constant over the 5 minute interval; the spectra of the halide ligands undergo a small shift (˜0.1 eV) to shallower work functions. For the energy levels reported in this work, only the first scan (labeled here as “1 min”) from a given sample is utilized to minimize charging and sample damage (a practice in UPS studies of organic or hybrid organic-inorganic materials) and the energy levels of 2-4 separate samples thus determined are averaged to generate the final values presented in FIG. 1E. See, for example, Greiner, M. T. et al., Nat. Mater. 2012, 11, 76-81, which is incorporated by reference in its entirety.

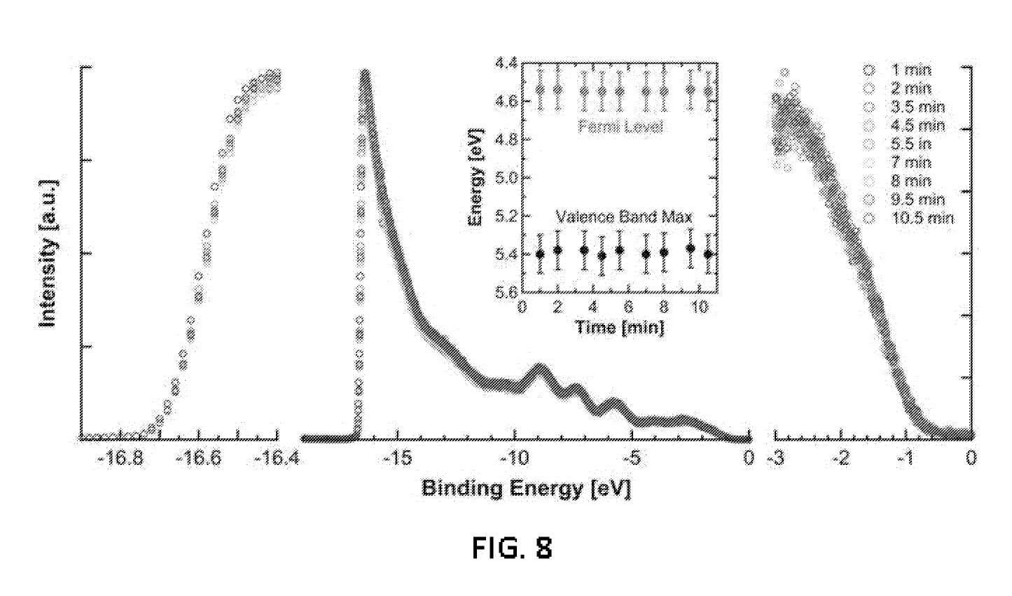

FIG. 8 shows the energies of the valence band maximum (VBM) and Fermi level of 1,3-BDT-exchanged PbS QDs over nine sequential scans. Neither the valence band energy nor the Fermi energy undergo shifts over this time interval. FIG. 8 shows time-dependence of energy levels determined from UPS spectra of 1,3-BDT-treated PbS QDs (λ=963 nm first absorption peak in solution). In FIG. 8, error bars here indicate experimental accuracy. No experimentally significant difference in energy levels is observed.

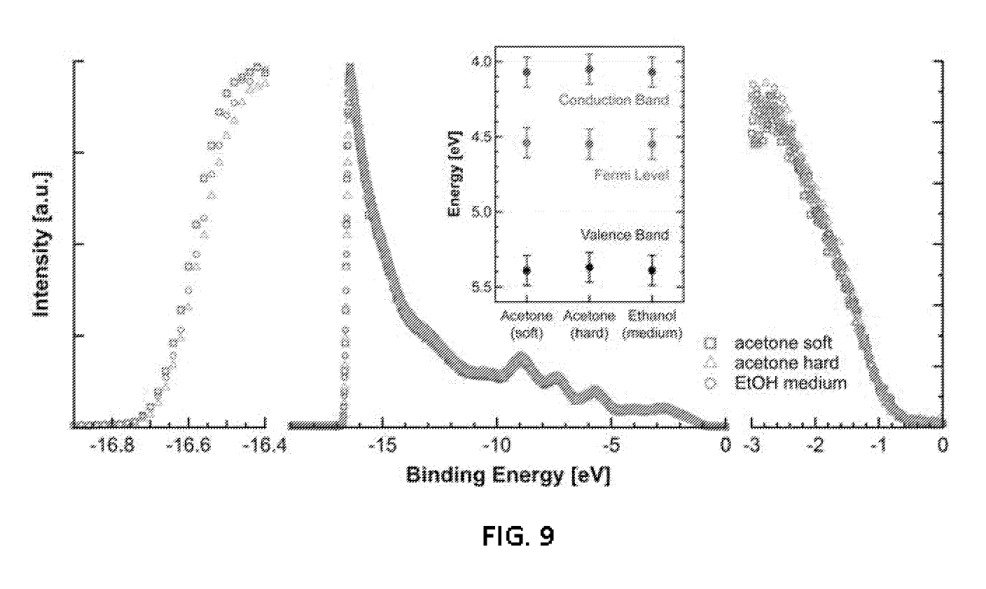

Given the high sensitivity of UPS to changes in surface chemistry, it is important to verify that unintended differences in sample preparation and sample history do not influence the measured energy levels. All of the quantum dots utilized in FIG. 1 are from a single synthetic batch, so variations in QD size should be minimal. The surface chemistry and ligand coverage of QDs could potentially be affected by the purification procedure and the strength with which the QDs are “crashed out” of solution by nonsolvent before centrifugation and resuspension. FIG. 9 shows energy levels determined from UPS spectra of PbS QDs exchanged with 1,3-BDT following three different crashout procedures: a “soft” crashout employing the addition of a minimal amount of acetone in the precipitation step, a “hard” crashout employing a large excess of acetone, and a crashout employing ethanol in place of acetone. It is observed that each of these different crashout procedures results in the same energy level values, indicating that the differences reported in FIG. 1 are due to the ligands used for ligand exchange rather than differences in QD synthesis or purification. It is also worthwhile to note that the length of exposure of the samples to ultrahigh vacuum (UHV) during UPS testing is only 1 hour, comparable to the length of time that the QD samples are exposed to high vacuum during the evaporation of contacts for solar cell fabrication. FIG. 9 shows dependence of UPS results on QD purification procedure for 1,3-BDT-exchanged PbS QDs (λ=963 nm first absorption peak in solution). In FIG. 9, error bars here indicate experimental accuracy. No experimentally significant difference in energy levels is observed.

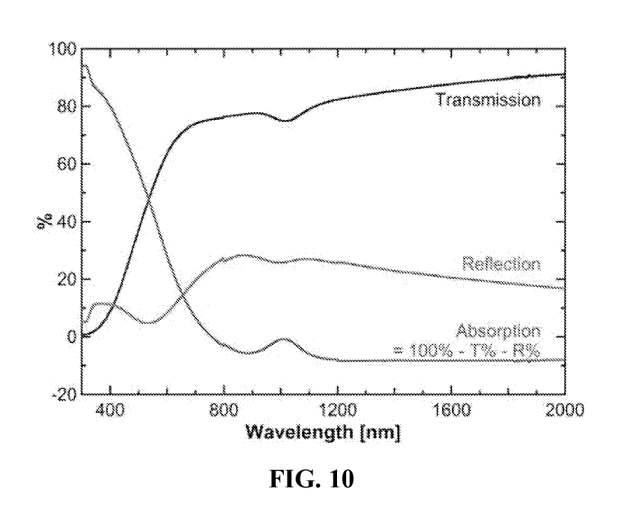

FIG. 10 shows representative optical transmission, reflection, and absorption spectra, where A %=100% T %−R %, of 1,3-BDT-exchanged PbS QDs (λ=963 nm first absorption peak in solution) measured during brief exposure to air. A 100 nm thick QD film, employing 5 sequential layers of spin-cast and ligand-exchanged QDs, is deposited onto glass treated with 3-mercaptopropyltrimethoxysilane as described in the Methods section. Reflection is measured at an incident angle of 8° from normal. Scattering is not accounted for; the presence of scattering gives rise to an offset in the computed absorption curve, but does not affect the value of the bandgap determined from the first excitonic peak of the absorption spectrum. FIG. 10 shows optical transmission, reflection, and absorption of 1,3-BDT-exchanged PbS QDs (λ=963 nm first absorption peak in solution).

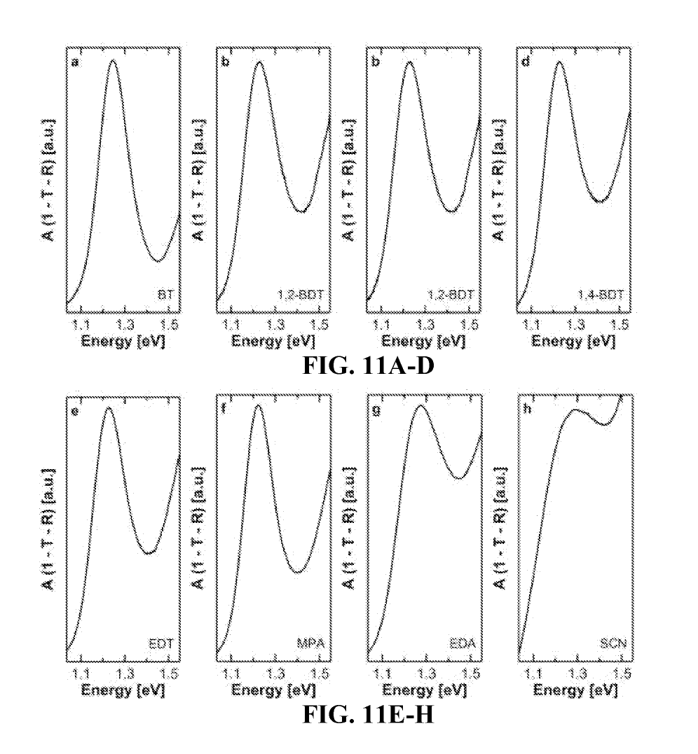

FIG. 11 shows optical absorption spectra of ligand-exchanged PbS QDs. In FIG. 11, lead sulfide QDs (λ=963 nm first absorption peak in solution) are exchanged with: A, benzenethiol; B, 1,2-benzenedithiol; C, 1,3-benzenedithiol; D, 1,4-benzenedithiol; E, 1,2-ethanedithiol; F, 3-mercaptopropionic acid; G, ethylenediamine; H, ammonium thiocyanate; I, tetrabutylammonium fluoride; J, tetrabutylammoniurn chloride; K, tetrabutylammonium bromide; L, tetrabutylammonium iodide.

FIG. 11 shows the collected optical absorption spectra of PbS QDs (λ=963 nm first absorption peak in solution) exchanged with each of the twelve ligands shown in FIG. 1, collected during brief exposure to air. The optical bandgap E_{g}^{opt} is determined from the energy of the peak of the first excitonic absorption feature of an 11-point boxcar average of the presented data. The transport bandgap E_{g} is determined from the equation

$${E}_{g} = {E}_{g}^{opt} + 1.786 \frac{{e}^{2}}{4 π {ɛ}_{0} {ɛ}_{QD} R} , \qquad ( 1 )$$

where e is the charge of the electron, ∈₀ is the permittivity of free space, ∈_{QD} is the optical dielectric constant of the QD core material (∈_{∞}^{PBS}=17.2), and R is the quantum dot radius. See, for example, Brus, L. J. Phys. Chem, 1986, 90, 2555-2560; Dalven, R. Solid State Phys. 1974, 28, 179-224, each of which is incorporated by reference in its entirety. The QD radius is determined by matching the first absorption peak in solution to a power law extrapolation of the sizing curve. An additional stabilization due to the interaction between a charge on a QD and its induced image charge across the dielectric boundary between the QD and the ligand matrix takes the form

$${E}^{pol} = \frac{{e}^{2}}{4 π {ɛ}_{0} R} ( {ɛ}_{matrix}^{- 1} - {ɛ}_{QD}^{- 1} ) , \qquad ( 2 )$$

where ∈ₘₐₜᵣᵢₓ is the optical dielectric constant of the ligand shell; previous studies have shown that this term is negligible in ligand-exchanged QD systems, so it is neglected here. See, for example, Jasieniak, J. et al., ACS Nano 2011, 5, 5888-902, which is incorporated by reference in its entirety. FIG. 13 shows the optical absorption spectra of the three PbS QD sizes utilized in FIG. 5, spin-coated onto glass and exchanged with 1,3-BDT ligands. As described above, the optical bandgaps are determined from the energy of the peak of the first excitonic absorption feature (for the highest-bandgap dots, in which only a shoulder is observed, the optical bandgap is determined from the minimum of the second derivative of the absorption profile in the shoulder region), and the transport bandgaps are determined from equation (1) using the sizing curve in Jasieniak. See, Jasieniak, J. et al., ACS Nano 2011, 5, 5888-902, which is incorporated by reference in its entirety. FIG. 13 shows optical absorption spectra of 1,3-BDT-exchanged PbS QDs used in FIG. 5, labeled by D, the QD diameter, and λₛₒₗₙ, the first absorption peak in solution. Spectra are vertically offset for clarity.

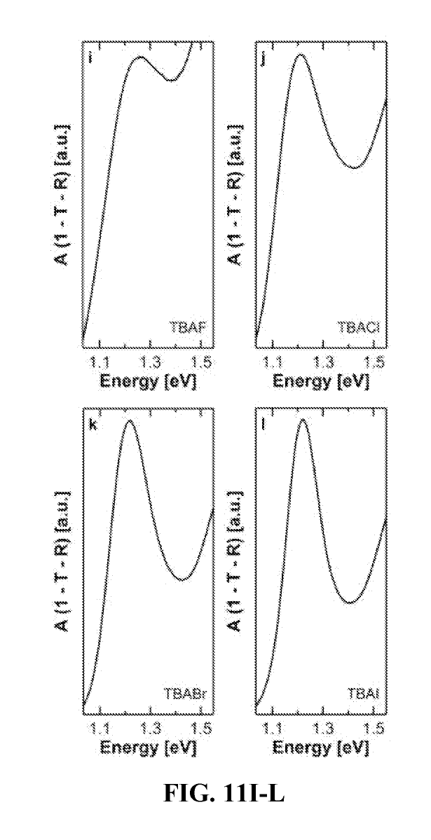

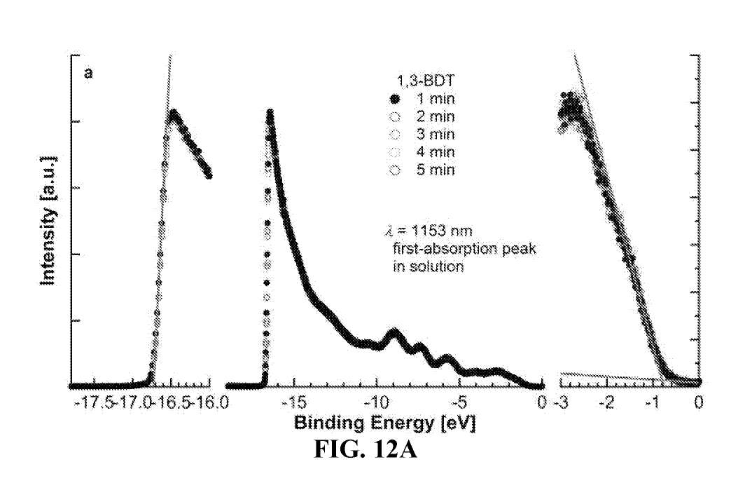

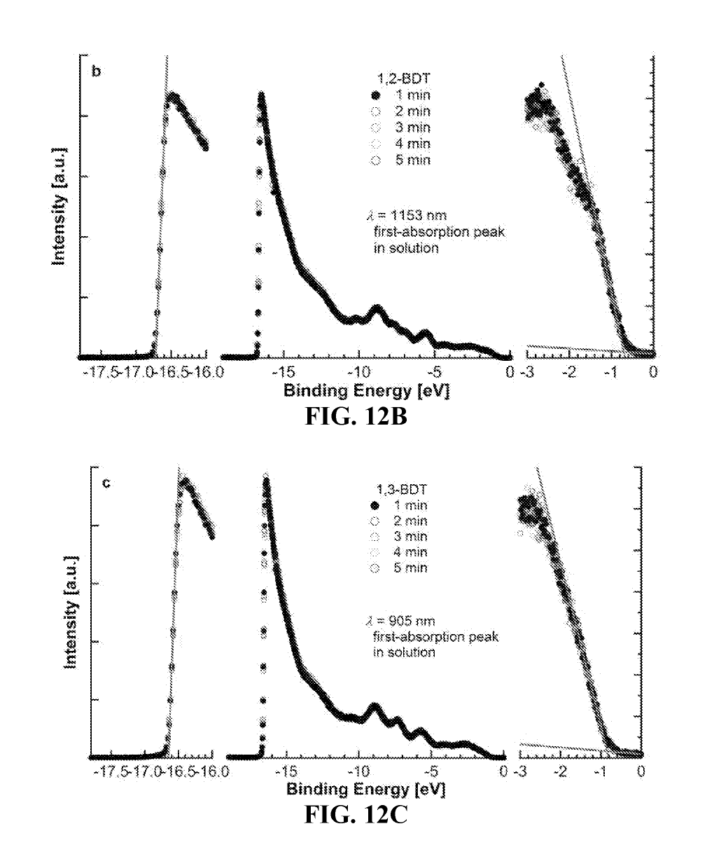

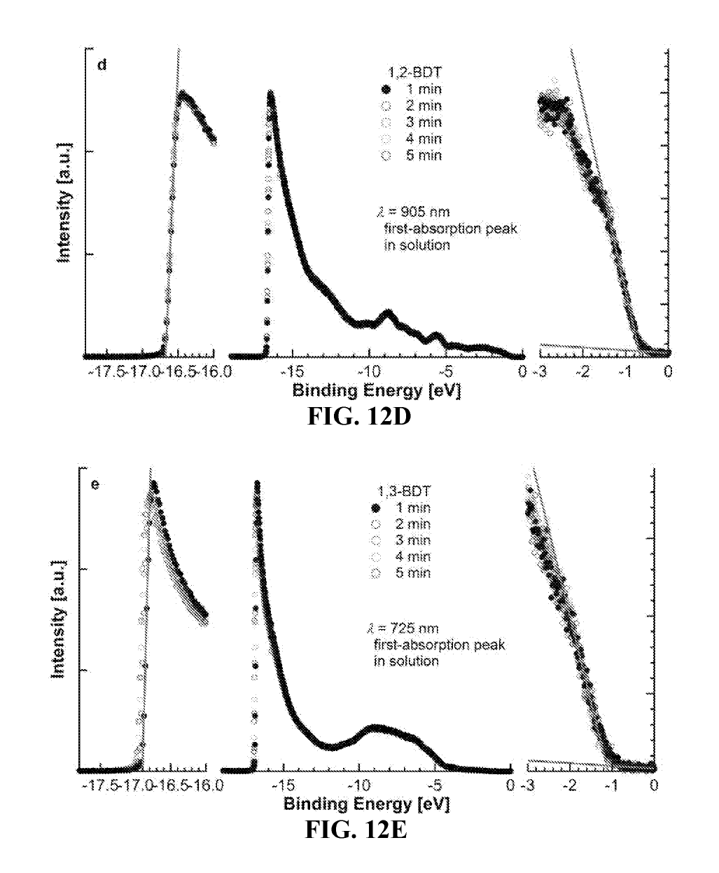

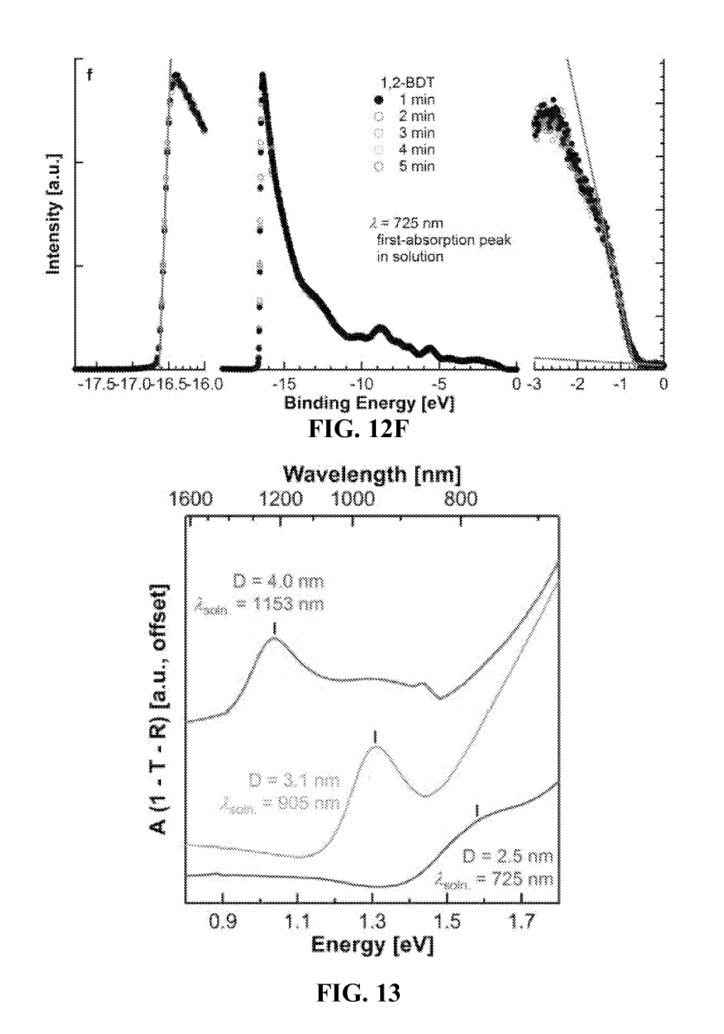

FIG. 12 shows UPS spectra of PbS QDs of varying size. In FIG. 12, lead sulfide QDs are deposited as ˜100 nm thick layers (5 sequential spin casting cycles) onto gold substrates. Samples consist of QDs with λ=1153 nm first absorption peak in solution exchanged with A, 1,3-BDT and B, 1,2-BDT; QDs with λ=905 nm first absorption peak in solution exchanged with C, 1,3-BDT and D, 1,2-BUT; and QDs with λ=725 nm first absorption peak in solution exchanged with E, 1,3-BUT and F, 1,2-BDT.

FIG. 12 shows the collected UPS spectra of the 1,2-BUT- and 1,3-BDT-exchanged PbS QDs utilized in FIG. 5. As in FIG. 7, five sequential scans are shown to demonstrate the lack of considerable variation in the spectra over time; only the fit to the first scan in each case is used to determine the energy levels.

### Ligand Binding Simulations on Pb-Rich PbS(111) Surface

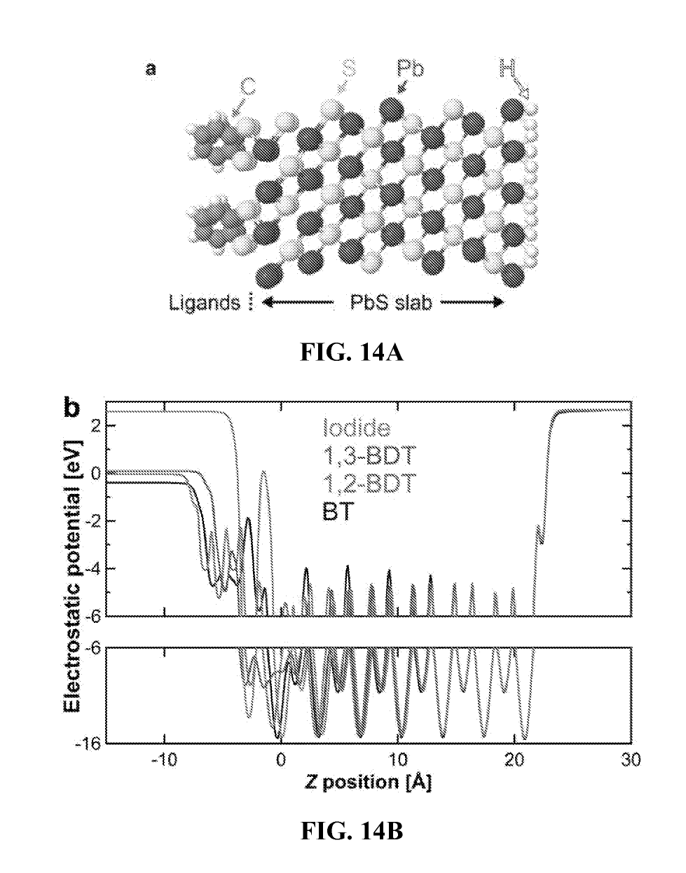

Atomistic DFT of the binding of ligands to PbS(111) surfaces to complement the discussion of binding to PbS(100) surfaces can be simulated, and both (100) and (111) facets can be dominant for PbS QDs. See, for example, Choi, J. J. et al., J. Am. Chem. Soc. 2011, 133, 3131-8; Cho, et al., J. Am. Chem. Soc. 2005, 127, 7140-7; Sealing, C. R. et al., ACS Nano 2012, 6, 2118-27, each of which is incorporated by reference in its entirety. The binding of BT, 1,2-BDT, 1,3-BDT, and iodide ligands to lead-rich PbS(111) planes can be simulated; the binding of 1,4-BDT to the PbS(111) surface was found to be unstable. FIG. 14A shows a schematic diagram of the modeled PbS(111) slabs. Pseudohydrogen atoms with fractional charges of 5/3 e passivate the lead atoms on the right, and ligands (1,2-BDT is shown as an example in FIG. 10A) passivate the lead atoms on the left. FIG. 14B shows plane-averaged electrostatic potential plots of PbS(111) slabs with different ligands. Different ligands exhibit different vacuum level shifts (ΔE_{vac}): for iodide, 1,3-BDT, 1,2-BDT, and BT, the vacuum energy shifts are ΔE_{vac}=+2.58 eV, +008 eV, −0.03 eV, and −039 eV, respectively. The direction of this trend in vacuum energy for binding to the lead-rich PbS(111) surface is the same as that observed in FIG. 2 for binding to the PbS(100) surface.

FIG. 14 shows DFT calculations of ligand-induced energy level shifts for binding to the PbS(111) surface FIG. 14A shows schematic diagram of modeled PbS(111) slab. The left side of the slab is passivated by the ligand (1,2-BDT is shown here as an example) and the right side is passivated by appropriate pseudo-hydrogen atoms to ensure charge balance. FIG. 14B shows plane-averaged electrostatic potentials of PbS(111) slabs with different ligands. The potential in the vacuum region far to the left of an unpassivated PbS slab is set to zero. The direction of the trend in energy level shifts observed here matches the trend observed in FIG. 2.

### Monodentate and Bidentate Ligand Binding Simulations on PbS(100) Surface

The bidentate thiol ligands used here (1,2-BDT, 1,3-BDT, 1,4,-BDT, and EDT) can bind to the PbS(100) surface in multiple configurations. In monodentate attachment, one of the two thiol groups of a given ligand is bound to a single QD as thiolate; the second thiol is either protonated and unbound to a QD, or is bound to an adjacent QD. In bidentate attachment, both of the thiol groups bind to a single QD; for the PbS(100) facet, these thiols would either bind to nearest neighbor Pb atoms (with a separation of 4.2 Å along the <110> direction) or next-nearest neighbor Pb atoms (with a separation of 6.0 Å along the <100> direction).

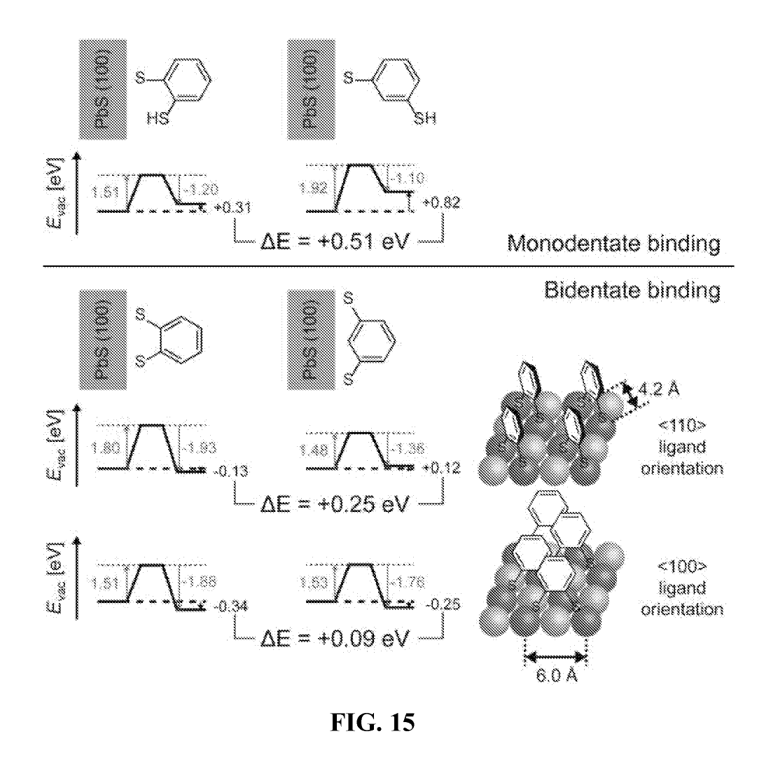

The single monodentate binding mode and both bidentate binding modes of 1,2-BDT and 1,3-BDT on the PbS(100) surface was investigated. FIG. 15 displays the results of DFT calculations for each of these three binding modes for both ligands. For each of the three binding modes considered, ΔE_{vac} for 1,3-BDT is higher than for 1,2-BDT; this shift in ΔE_{vac} leads to a deeper valence band for 1,3-BDT-treated PbS QDs than for 1,2-BDT-treated PbS QDs, reproducing the trend observed by UPS in FIG. 1 and by photovoltaic measurements in FIGS. 4-5, FIG. 15 shows vacuum energy shifts for binding of 1,2-BDT and 1,3-BDT to the PbS(100) surface in various geometries. In FIG. 15, the energy level shift ΔE_{vac} for each configuration is decomposed into components from the interfacial dipole (red; positive contribution) and the intrinsic ligand dipole (blue; negative contribution). ΔE here corresponds to the difference in vacuum energy shift between 1,2-BDT and 1,3-BDT for a given binding mode (monodentate: bidentate with <110> ligand orientation; or bidentate with <100> ligand orientation).

Simulations of PbS Slabs with Double-Sided Ligand Passivation.

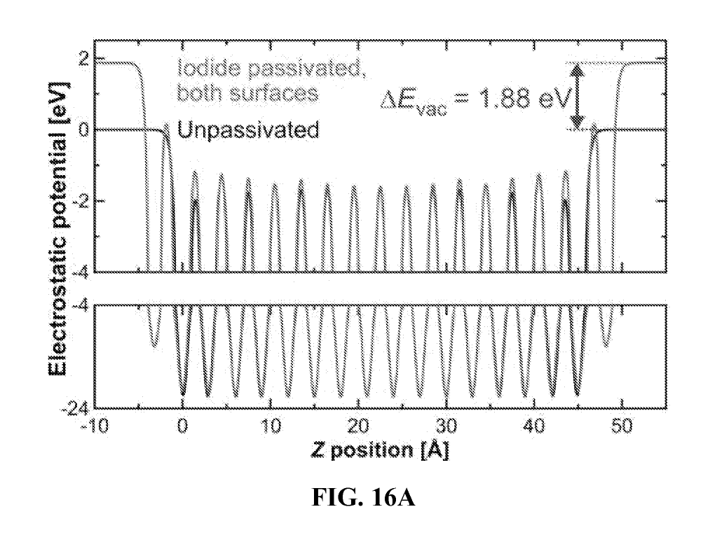

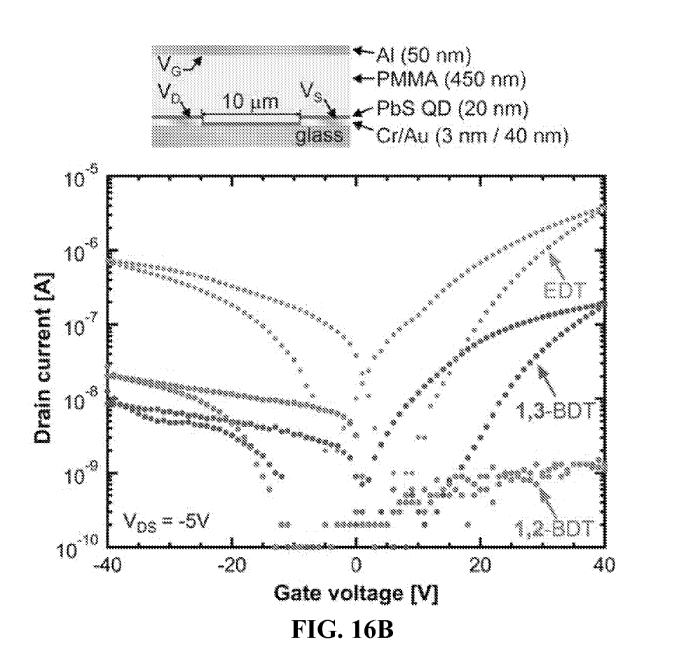

The simulations treat the QD surface as a semi-infinite quasi-two-dimensional slab, with ligands bound to one side of the slab and charge-balancing pseudohydrogen atoms bound to the other side. This approximation is utilized in order to increase computational efficiency and facilitate comparisons between different ligands. In reality, the entire surface of the three-dimensional QD is expected to be passivated by ligands. To verify this single-side binding model and move the simulations a step closer to physical reality, DFT simulations were performed on a PbS(100) slab passivated on both sides by iodide ligands, in comparison to an unpassivated PbS(100) slab. FIG. 16 shows plane-averaged electrostatic potential plots of these two systems. The arbitrary y-axis offset for each case is chosen such that the electrostatic potentials align in the center of the PbS slab and the vacuum energy outside the unpassivated slab is zero. The shift in vacuum energy observed here for double-sided iodide passivation of ΔE_{vac}=1.88 eV is in close agreement with the vacuum energy shift observed for single-sided iodide passivation of ΔE_{vac}=1.90 eV, FIG. 16A shows DFT simulations of double-sided ligand binding to a PbS(100) slab. In FIG. 16, the vacuum energy is set to zero outside the unpassivated PbS slab, and the arbitrary offset of the iodide-passivated PbS slab is chosen such that the electrostatic potentials align in the center of the slab. Close agreement is observed between the vacuum energy shill observed here for double-sided iodide passivation (ΔE_{vac}=1.88 eV) and the vacuum energy shift observed for single-sided iodide passivation (ΔE_{vac}=1.90 eV). FIG. 16B shows transfer curves of PbS QD FETs. The top panel provides a schematic cross section of the device structure.

### Field-Effect Mobility, Recombination Rate, and Density of States of Ligand-Exchanged PbS QDs

As shown in FIG. 3, PbS QDs exchanged with EDT, 1,2-BDT, and 1,3-BDT behave differently in ZnO/PbS np heterojunction (NP HJ) and Schottky junction (SJ) architectures. If trap density and carrier mobility, density, and recombination rates were the sole source of variation between PbS QDs treated with these ligands, the same relative performance would be expected between these three ligand treatments for both architectures; if energy levels were the sole source of variation, the rank order of performance for the different ligands would be either unchanged or inverted between the two architectures. Instead, EDT shows the worst performance in both architectures; 1,3-BDT outperforms 1,2-BDT in the NP HJ architecture, and 1,2-BDT outperforms 1,3-BDT in the SJ architecture. As expected, ligand exchange brings about changes in both the trap and carrier properties and the energy levels of the QDs. Here, through a combination of field-effect mobility, recombination, and trap density measurements, differences in trap and carrier properties between the three ligands tested can be quantified, showing that they can explain the poor performance of EDT but not the shift in performance for 1,2-BDT and 1,3-BDT.

Field-Effect Transistor Fabrication and Testing.

Field-Effect Transistor (FET) devices utilize a bottom-contact top-gate geometry. Briefly, the source and drain electrodes consist of Cr(3 nm)/Au(40 nm) interdigitated arrays with length (L) and width (W) of L=10 um and W=12 mm, respectively, thermally evaporated onto glass and patterned via liftoff (Thin Film Devices). The substrates are pretreated with 3-MPTMS as described in the Methods section, and a single layer of ligand-exchanged PbS QDs is deposited by sequential spin-casting. The gate dielectric, 950 PMMA A4 resist (Microchem), is spin-cast at 1000 rpm for a thickness of ˜470 nm. The top-contact aluminum gate is deposited by thermal evaporation through a shadow mask. FET measurements are performed using an Agilent 4156C semiconductor parameter analyzer. Individual current-voltage sweeps are conducted in <400 ms to minimize bias stress. The capacitance of the insulating gate dielectric is measured for a QD-free device using a Solartron 1260 impedance analyzer.

Transient-V_{OC} Measurements.

Transient-V_{OC} measurements are performed on ZnO/PbS NP HJ devices. The device is biased by white light from a xenon lamp passed through a liquid light guide and neutral density filter onto the active area. A low-intensity perturbation is provided by a λ=635 nm laser chopped at 11 Hz and co-focused onto the active area through a variable neutral density filter. The intensity of the laser is adjusted such that the voltage perturbation ΔV is less than 5% of the V_{OC} generated by the white light bias. Transient-voltage curves are collected from the trailing edge of the perturbation pulse using the high-impedance input of a Tektronix 3054B oscilloscope.

Density of States Measurements.

Density of states measurements are performed. As in the transient-V_{OC} measurements described above, white bias light of variable intensity is provided by a xenon lamp. Laser pulses of 300 ns duration, produced by modulating the output of a λ=635 nm laser using an Agilent 33220A function generator, are co-focused onto the active area. The white light bias intensity and laser pulse intensity are modulated using neutral density filters such that the voltage perturbation ΔV is less than 5% of the V_{OC} generated by the white light bias. Transient responses are measured using a Tektronix 3054B oscilloscope set to an input impedance of 1 MΩ: voltage traces are collected using an ADA400A high-impedance probe, and current traces are collected using a DHPCA-100 preamplifier.

Carrier mobilities of ligand-exchanged PbS QD films are extracted from the FET transfer characteristics, collected in the linear regime with an absolute drain-source bias (|V_{DS}|) of 5 V as shown in FIG. 16. Electron and hole mobilities are determined from the n-channel and p-channel response, respectively, by fitting the linear regions of the I_{DS}-V_{G} curve to the equation

$$\frac{\partial {I}_{DS}}{\partial {V}_{G}} {\vert}_{{V}_{DS}} = \frac{W}{L} {C}_{i} {V}_{SD} μ , \qquad ( 3 )$$

where J_{DS} is the drain-source current, V_{G} is the gate bias, L and W are the length (10 μm) and width (12 mm), respectively, of the channel, and C; is the capacitance of the insulating gate dielectric (measured to be 5.7 nF cm⁻²), The observed hysteresis results from bias-stress within the QD channel; this phenomenon is rigorously examined elsewhere. See, for example, Osedach, T. P. et al., ACS Nano 2012, 6, 3121-7; Ip, A. H. et al., Nat. Nanotechnol. 2012, 7, 577-82, each of which is incorporated by reference in its entirety. Mobilities are extracted from the branch of the transfer curve starting at V_{G}=0 and scanning toward higher absolute gate biases. The extracted electron mobility μ_{c} and hole mobility μₕ for each ligand treatment are μ_{c}=5×10⁻³ cm²V⁻¹s⁻¹ and μₕ 6×10⁻⁴ cm²V⁻¹s⁻¹ for EDT; μₕ=1×10⁻⁵ cm²V⁻¹s⁻¹ for 1,2-BDT (no n-channel turn-on observed); μₑ=2×10⁻⁴ cm²V⁻¹s⁻¹ and μₕ=9×10⁻⁶ cm²V⁻¹s⁻¹ for 1,3-BDT. EDT-treated PbS QD films thus demonstrate significantly higher carrier mobilities than either 1,2-BDT- or 1,3-BUT-treated films.

In the absence of other differences between ligands, a higher carrier mobility should lead to a higher performance in photovoltaics employing EDT-exchanged PbS QDs; instead, 1,2-BDT and 1,3-BDT-exchanged PbS QDs display a higher performance in both NP HJ and SJ architectures. Transient current and voltage analysis of NP HJ photovoltaics employing 1,2-BDT-, 1,3-BDT, and EDT-exchanged QDs indicates that the higher mobility of EDT-exchanged QDs is outweighed by their higher carrier recombination rate and trap density.

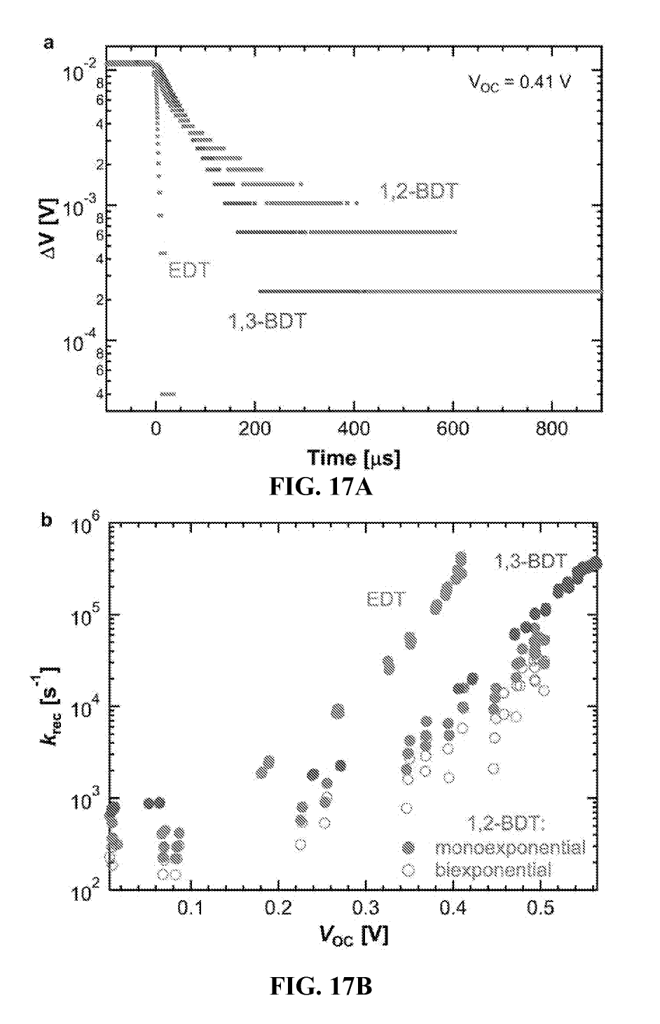

FIG. 17 shows transient-V_{OC} analysis. FIG. 17A shows decay in ΔV (where ΔV is the additional V_{OC} induced by the perturbing laser pulse) following turn-off of the perturbation pulse for ZnO/PbS QD NP HJ devices employing EDT, 1,2-BDT, and 1,3-BDT ligand exchange. FIG. 17B shows extracted recombination rate coefficients k_{rec} for NP HJ photovoltaics across a range of bias light intensities and induced photovoltages. For each induced V_{OC}, the intensity of the perturbation source is adjusted such that ΔVₘₐₓ is less than 5% of V_{OC}. Recombination rate coefficients for EDT and 1,3-BDT correspond to fits to monoexponential decay kinetics; recombination rate coefficients for both monoexponential and biexponential fits for 1,2-BDT are shown.

FIG. 17A shows the transient voltage response, immediately after the turn-off of a perturbing illumination pulse, of ZnO/PbS QD NP HJ photovoltaics biased at V_{OC}=0.41 V by white light illumination. EDT treatment gives rise to a much more rapid voltage decay than 1,2-BDT and 1,3-BDT treatment. This decay can be fit to monoexponential kinetics for EDT and 1,3-BDT and biexponential kinetics for 1,2-BDT to enable calculation of the recombination rate constant k_{rec}. FIG. 17B shows the extracted k_{rec} values for EDT-, 1,2-BDT-, and 1,3-BDT-exchanged PbS QDs in NP photovoltaics across a range of bias light intensities and induced voltages. It is observed that at a given voltage and photoinduced charge density, EDT gives rise to a larger recombination rate coefficient than either of the benzenedithiols. A higher recombination rate translates into a higher dark current and lower V_{OC}, explaining the lower V_{OC} observed for photovoltaics employing EDT relative to those employing 1,2-BUT and 1,3-BDT.

Insight into the mechanism behind the higher recombination rate for EDT is gained by analysis of the profile of the density of electronic trap states within the bandgap. All measurements are performed on ZnO/PbS QD NP HJ devices. The device is held at a given V_{OC} and corresponding quasi-Fermi-level splitting through illumination with a white light bias. A short perturbation laser pulse (300 ns duration) generates an excess of carriers of density Δn, giving rise to an increase in photovoltage ΔV. The induced photovoltage ΔV for a given carrier density Δn depends on the density of states dN/dE at the quasi-Fermi level energy corresponding to the specified V_{OC}; for a given Δn, a larger density of states will result in a smaller ΔV, as the quasi-Fermi level only increases enough to fill Δn states. Thus, by plotting Δn/ΔV as a function of V_{OC}, the profile of the density of electronic states within the bandgap (i.e. the density of trap states) can be determined.

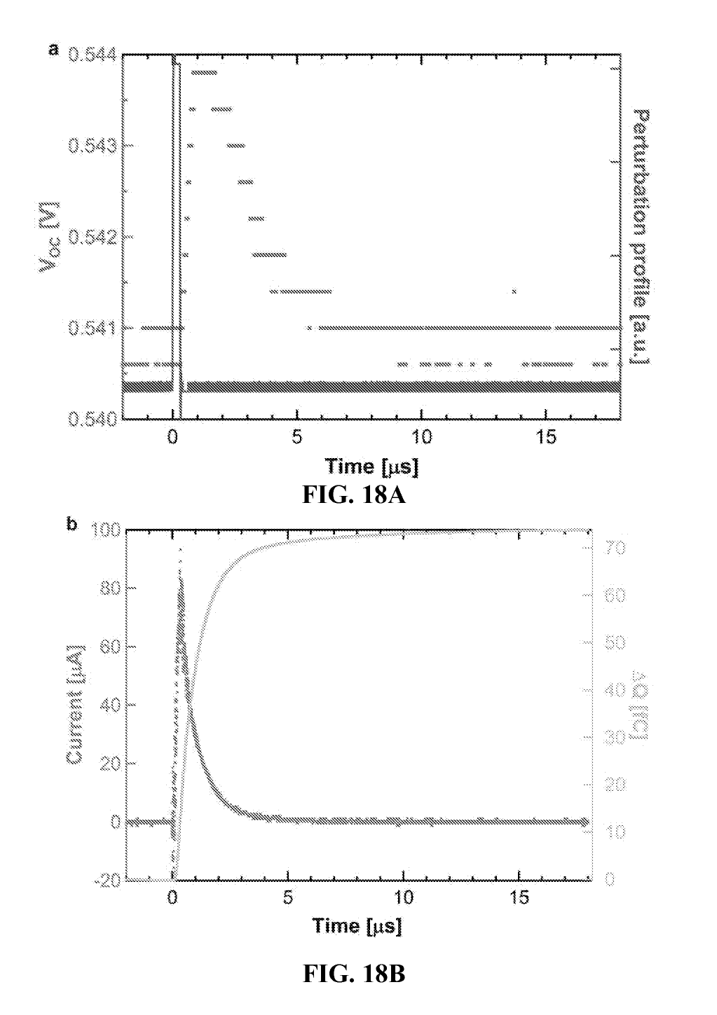

FIG. 18A shows the voltage response of a 1,3-BDT-exchanged PbS QD NP HJ device at a given white light bias following excitation with a perturbation laser pulse of a given intensity. The height of the induced voltage pulse gives ΔV. To determine Δn for this perturbation intensity, the white light bias is turned off and the transient current response of the device to the perturbation pulse alone is measured, as shown in FIG. 188. Integration of this complete current profile provides ΔQ=AeΔn (A is the device area; e is the charge of the electron) for this perturbation intensity. FIG. 18A shows transient voltage response of a ZnO/PbS QD NP HJ photovoltaic device to a perturbation light pulse under white light bias. The voltage response is plotted against the left axis, and the profile of the perturbation pulse is plotted against the right axis. The height of the voltage peak above the baseline yields ΔV. FIG. 18B shows transient current response of the same device to the same perturbation pulse without white light bias. The current response is plotted against the left axis and the integrated charge is plotted against the right axis. The rightmost value of the integrated charge yields the value of ΔQ=AeΔn used to compute the density of states profile.

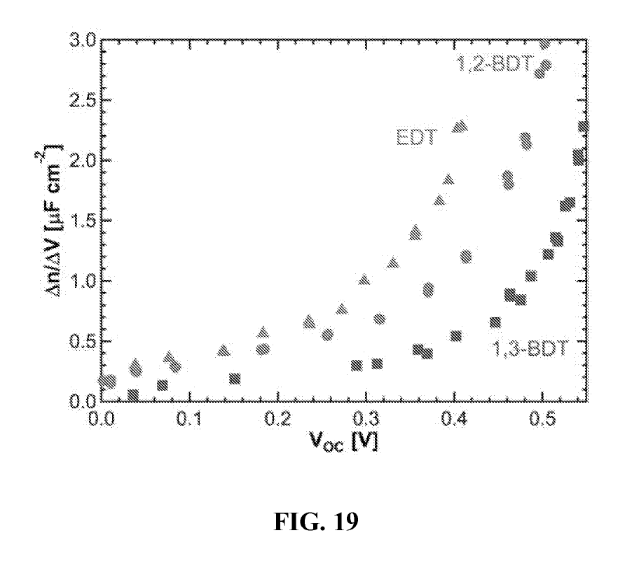

A complete plot of Δn/AΔ as a function of quasi-Fermi-level splitting is obtained by varying the intensity of the bias light (and, correspondingly, the induced V_{OC}) and measuring ΔV and Δn at each intensity. The intensity of the perturbing laser pulse is adjusted to keep ΔV less than 5% of V_{OC} at each bias light intensity. FIG. 19 shows the calculated density of states profiles for ZnO/PbS QD NP HJ photovoltaics employing EDT-, 1,2-BDT, and 1,3-BDT-exchanged QDs. The density of states for EDT increases much more rapidly than for 1,2-BDT or 1,3-BDT, corresponding to a greater density of trap states within the bandgap for EDT-treated PbS QDs. It should be noted that this method does not specify whether the measured density of states corresponds to electron states or hole states; as the electron and hole quasi-Fermi levels achieve greater separation at higher V_{OC} values, both electron and hole traps could contribute to the response. FIG. 19 shows trap density profile, measured in terms of Δn/ΔV, for ZnO/PbS QD NP HJ photovoltaic devices employing ligand exchange with EDT, 1,2-BDT, or 1,3-BDT.

The higher recombination rate and trap density for EDT-exchanged PbS QDs thus outweighs their higher carrier mobility, explaining why EDT-treated PbS QDs generate a lower V_{OC} in both the NP HJ and SJ architectures than 1,2-BDT and 1,3-BDT-treated PbS QDs. However, the differences in mobility, recombination rate, and trap density described here do not explain the difference in performance between 1,2-BDT and 1,3-BDT in the NP HJ and SJ architectures. These findings, in conjunction with the data reported herein, highlight the importance of taking into account both changes in carrier transport properties and dipole-induced energy level shifts in the comparison of different ligand treatments for QD optoelectronic devices.

### Solar Cell Spectral Mismatch

External quantum efficiency measurements are performed by passing chopped white light from a xenon lamp (Thermo Oriel 66921) through a monochromator into a single-core optical fiber and onto the active device in an underfilled illumination geometry; the device current is measured using a lock-in amplifier (Stanford Research Systems SR830).

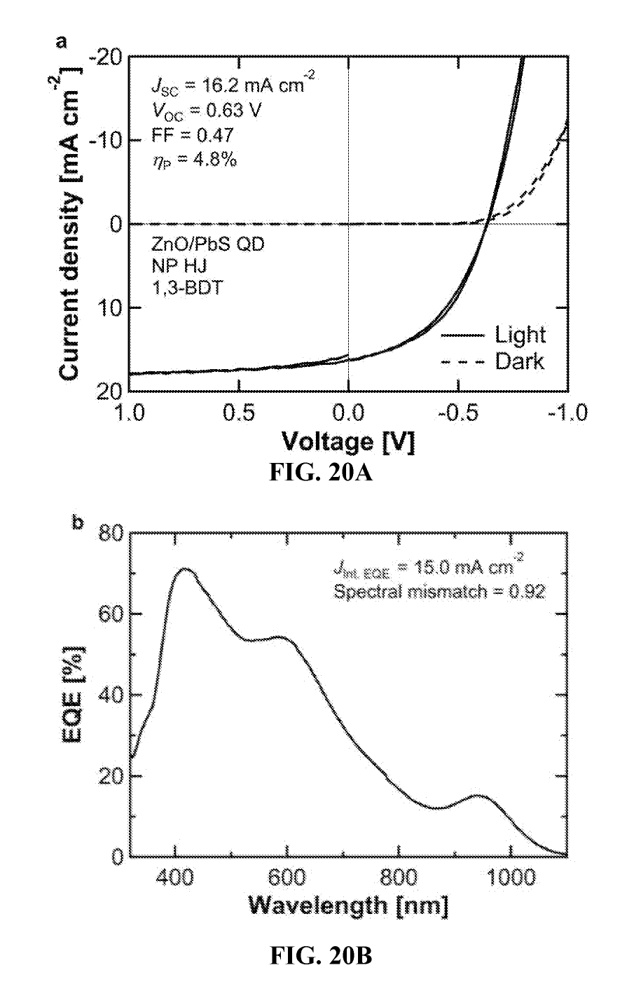

FIG. 20 shows the measured and external quantum efficiency (EQE) response of a ZnO/PbS QD NP HJ device employing 1,3-EDT-treated QDs. Integrating the product of the EQE spectrum with the AM1.5G solar spectrum yields an expected J_{SC} under solar illumination of 15.0 mA cm⁻²; comparison with the measured J_{SC} of 16.2 mA cm⁻² yields a spectral mismatch of 0.92. FIG. 20A shows current-voltage response of a ZnO/PbS QD np heterojunction photovoltaic device under illumination with a filtered xenon lamp. FIG. 206 shows external quantum efficiency spectrum of the same device.

Other embodiments are within the scope of the following claims.

1. A method of improving performance of a photovoltaic device comprising modifying a surface energy level of a semiconductor nanocrystal of the device through ligand exchange.

2. The method of claim 1, wherein the ligand includes a thiol.

3. The method of claim 1, wherein the ligand includes an amine.

4. The method of claim 1, wherein the ligand includes a halide.

5. The method of claim 1, wherein the semiconductor nanocrystal includes a lead sulfide.

6. The method of claim 1, wherein the ligand includes a benzenethiol (BT), a 1,2-benzenedithiol, a 1,3-benzenedithiol, a 1,4-benzenedithiol, a 1,2-ethanedithiol, or a 3-mercaptopropionic acid.

7. The method of claim 1, wherein the ligand includes a 1,2-ethylenediamine or an ammonium thiocyanate.

8. The method of claim 1, wherein the ligand includes a tetrabutylammonium iodide, a tetrabutylammonium bromide, a tetrabutylammonium chloride, or a tetrabutylammonium fluoride.

9. A photovoltaic device having improved performance comprising:
a first electrode;
a first charge transporting layer in contact with the first electrode;
a second electrode;
a second charge transporting layer in contact with the second electrode; and
a plurality of semiconductor nanocrystals made by modifying a surface energy level of a semiconductor nanocrystal of the device through ligand exchange and disposed between the first charge transporting layer and the second charge transporting layer, wherein a surface of the plurality of semiconductor nanocrystals is modified through ligand exchange.

10. The photovoltaic device of claim 9, wherein the semiconductor nanocrystal includes a lead sulfide.

11. The photovoltaic device of claim 9, wherein the ligand includes a thiol.

12. The photovoltaic device of claim 9, wherein the ligand includes an amine.

13. The photovoltaic device of claim 9, wherein the ligand includes a halide.

14. The photovoltaic device of claim 9, wherein the ligand includes a benzenethiol (BT), a 1,2-benzenedithiol, a 1,3-benzenedithiol, a 1,4-benzenedithiol, a 1,2-ethanedithiol, or a 3-mercaptopropionic acid.

15. The photovoltaic device of claim 9, wherein the ligand includes a 1,2-ethylenediamine or an ammonium thiocyanate.

16. The photovoltaic device of claim 9, wherein the ligand includes a tetrabutylammonium iodide, a tetrabutylammonium bromide, a tetrabutylammonium chloride, or a tetrabutylammonium fluoride.

17. A semiconductor nanocrystal comprising a surface modified through ligand exchange, wherein the modification improves performance of a photovoltaic device comprising the semiconductor nanocrystal by modifying a surface energy level of a semiconductor nanocrystal of the device through ligand exchange.

18. The semiconductor nanocrystal of claim 17, wherein the ligand includes a thiol.

19. The semiconductor nanocrystal of claim 17, wherein the ligand includes an amine.

20. The semiconductor nanocrystal of claim 17, wherein the ligand includes a halide.

21. The semiconductor nanocrystal of claim 17, wherein the ligand includes a benzenethiol (BT), a 1,2-benzenedithiol, a 1,3-benzenedithiol, a 1,4-benzenedithiol, a 1,2-ethanedithiol, or a 3-mercaptopropionic acid.

22. The semiconductor nanocrystal of claim 17, wherein the ligand includes a 1,2-ethylenediamine or an ammonium thiocyanate.

23. The semiconductor nanocrystal of claim 17, wherein the ligand includes a tetrabutylammonium iodide, a tetrabutylammonium bromide, a tetrabutylammonium chloride, or a tetrabutylammonium fluoride.
